(19) United States
(12) Patent Application Publication
(10) Pub. No.: US 2025/0306083 A1
(43) Pub. Date: Oct. 2, 2025

(54) INSPECTION SYSTEM

(71) Applicant: Tokyo Electron Limited, Tokyo (JP)

(72) Inventors: Shingo MORITA, Tokyo (JP); Yoshinori FUJISAWA, Kumamoto (JP); Yoichi SHIMIZU, Austin, TX (US)

(21) Appl. No.: 19/238,982

(22) Filed: Jun. 16, 2025

Related U.S. Application Data
(63) Continuation of application No. PCT/JP2023/044372, filed on Dec. 12, 2023.

(30) Foreign Application Priority Data
Dec. 26, 2022 (JP) 2022-208570

(51) Int. Cl. G01R 31/28

(52) U.S. Cl. CPC G01R 31/2853

(57) ABSTRACT

An inspection system includes a semiconductor substrate on which a first inspection circuit and a second inspection circuit are formed, a measurer configured to measure a predetermined characteristic in each of the first inspection circuit and the second inspection circuit, and an estimator configured to estimate process variation when the first inspection circuit and the second inspection circuit are formed on the semiconductor substrate, based on a first measurement result obtained by the measurer measuring the first inspection circuit and a second measurement result obtained by the measurer measuring the second inspection circuit. A magnitude of a variation of the characteristic with respect to the process variation in the second inspection circuit differs from a magnitude of a variation of the characteristic with respect to the process variation in the first inspection circuit.

### CROSS-REFERENCE TO RELATED APPLICATIONS

This application is a continuation application of International Application No. PCT/JP2023/044372 filed on Dec. 12, 2023, and designated the U.S., which is based upon and claims priority to Japanese Patent Application No. 2022-208570 filed on Dec. 26, 2022, the entire contents of which are incorporated herein by reference.

### BACKGROUND

### 1. Technical Field

The present disclosure relates to an inspection system.

### 2. Description of Related Art

A test element group (TEG) formed on a semiconductor substrate is used for evaluating a semiconductor process or a device. Japanese Unexamined Patent Application Publication No. 2002-217258 (hereinafter, “Patent Document 1”) discloses a semiconductor device in which a plurality of TEGs are arranged in a scribe region. Japanese Unexamined Patent Application Publication No. 2000-012639 (hereinafter, “Patent Document 2”) discloses a test circuit for a plurality of monitor TEGs which are mounted together with a semiconductor device on the same chip and are distributed at discretionarily chosen positions in the chip.

### SUMMARY

According to one aspect of the present disclosure, an inspection system includes a semiconductor substrate on which a first inspection circuit and a second inspection circuit are formed, a measurer configured to measure a predetermined characteristic in each of the first inspection circuit and the second inspection circuit, and an estimator configured to estimate process variation when the first inspection circuit and the second inspection circuit are formed on the semiconductor substrate, based on a first measurement result obtained by the measurer measuring the first inspection circuit and a second measurement result obtained by the measurer measuring the second inspection circuit. A magnitude of a variation of the characteristic with respect to the process variation in the second inspection circuit differs from a magnitude of a variation of the characteristic with respect to the process variation in the first inspection circuit.

### BRIEF DESCRIPTION OF THE DRAWINGS

FIG. 1 is a diagram illustrating an overall configuration of an inspection system according to a first embodiment;

FIG. 2 is a diagram for explaining a semiconductor substrate of the inspection system according to the first embodiment;

FIG. 3 is a flowchart for explaining an inspection method using the inspection system according to the first embodiment;

FIG. 4 is a diagram illustrating an overall configuration of an inspection system according to a second embodiment;

FIG. 5 is a diagram for explaining an inspection circuit of the inspection system according to the second embodiment;

FIG. 6 is a diagram for explaining an inspection circuit of the inspection system according to the second embodiment;

FIG. 7 is a circuit diagram for explaining an element circuit included in an inspection circuit of an inspection system according to a third embodiment;

FIG. 8 is a circuit diagram for explaining an element circuit included in an inspection circuit of the inspection system according to the third embodiment;

FIG. 9 is a circuit diagram for explaining an element circuit included in an inspection circuit of the inspection system according to the third embodiment;

FIG. 10 is a circuit diagram for explaining an element circuit included in an inspection circuit of an inspection system according to a fourth embodiment;

FIG. 11 is a circuit diagram for explaining an element circuit included in an inspection circuit of the inspection system according to the fourth embodiment;

FIG. 12 is a diagram for explaining a structure of an element circuit included in an inspection circuit of an inspection system according to a fifth embodiment;

FIG. 13 is a diagram for explaining a structure of an element circuit included in an inspection circuit of the inspection system according to the fifth embodiment;

FIG. 14 is a diagram for explaining a structure of an element circuit included in an inspection circuit of the inspection system according to the fifth embodiment;

FIG. 15 is a diagram for explaining a structure of an element circuit included in an inspection circuit of the inspection system according to the fifth embodiment;

FIG. 16 is a diagram for explaining a structure of an element circuit included in an inspection circuit of an inspection system according to the fifth embodiment;

FIG. 17 is a diagram for explaining a structure of an element circuit included in an inspection circuit of the inspection system according to the fifth embodiment;

FIG. 18 is a diagram for explaining a structure of an element circuit included in an inspection circuit of the inspection system according to the fifth embodiment;

FIG. 19 is a diagram for explaining a structure of an element circuit included in an inspection circuit of the inspection system according to the fifth embodiment;

FIG. 20 is a diagram for explaining a structure of an element circuit included in an inspection circuit of the inspection system according to the fifth embodiment;

FIG. 21 is a diagram for explaining a structure of an element circuit included in an inspection circuit of the inspection system according to the fifth embodiment;

FIG. 22 is a diagram for explaining a structure of an element circuit included in an inspection circuit of the inspection system according to the fifth embodiment;

FIG. 23 is a diagram for explaining a structure of an element circuit included in an inspection circuit of the inspection system according to the fifth embodiment;

FIG. 24 is a diagram illustrating an overall configuration of an inspection system according to a sixth embodiment;

FIG. 25 is a diagram illustrating an overall configuration of an inspection system according to a seventh embodiment;

FIG. 26 is a diagram for explaining an inspection circuit of the inspection system according to the seventh embodiment;

FIG. 27 is a diagram for explaining an operation example of an inspection system according to the present embodiment;

FIG. 28 is a diagram for explaining an operation example of the inspection system according to the present embodiment;

FIG. 29 is a diagram for explaining an operation example of the inspection system according to the present embodiment;

FIG. 30 is a diagram for explaining an operation example of the inspection system according to the present embodiment;

FIG. 31 is a diagram for explaining an operation example of the inspection system according to the present embodiment;

FIG. 32 is a diagram for explaining an operation example of the inspection system according to the present embodiment;

FIG. 33 is a diagram for explaining an operation example of the inspection system according to the present embodiment;

FIG. 34 is a diagram for explaining an operation example of the inspection system according to the present embodiment;

FIG. 35 is a diagram for explaining an operation example of the inspection system according to the present embodiment;

FIG. 36 is a diagram for explaining an operation example of the inspection system according to the present embodiment;

FIG. 37 is a diagram for explaining an operation example of the inspection system according to the present embodiment;

FIG. 38 is a circuit diagram for explaining a modified example of the element circuit included in the inspection circuit of the inspection system according to the present embodiment;

FIG. 39 is a circuit diagram for explaining a modified example of the element circuit included in the inspection circuit of the inspection system according to the present embodiment;

FIG. 40 is a circuit diagram for explaining another modified example of the element circuit included in the inspection circuit of the inspection system according to the present embodiment; and

FIG. 41 is a circuit diagram for explaining another modified example of the element circuit included in the inspection circuit of the inspection system according to the present embodiment.

### DETAILED DESCRIPTION

The present disclosure provides a technique for estimating process variations in a semiconductor process.

Embodiments will be described below with reference to the accompanying drawings. It is to be understood that the present disclosure is not limited to these examples, but is intended to be indicated by the claims and to include all modifications within the meaning and scope of equivalents of the claims.

In the description and drawings of each embodiment, the same or corresponding reference numerals are used to designate the same or corresponding components, and the repeated description is omitted. In addition, for ease of understanding, the scale of each part in the drawings may be different from the actual scale.

### First Embodiment

An inspection system according to the first embodiment will be described. The inspection system according to the first embodiment estimates process variation for a semiconductor substrate when a first inspection circuit and a second inspection circuit are formed on the semiconductor substrate. The inspection system according to the first embodiment estimates process variation by measuring characteristics in the first inspection circuit and the second inspection circuit having different variations in characteristics with respect to a process variation.

### <Inspection System>

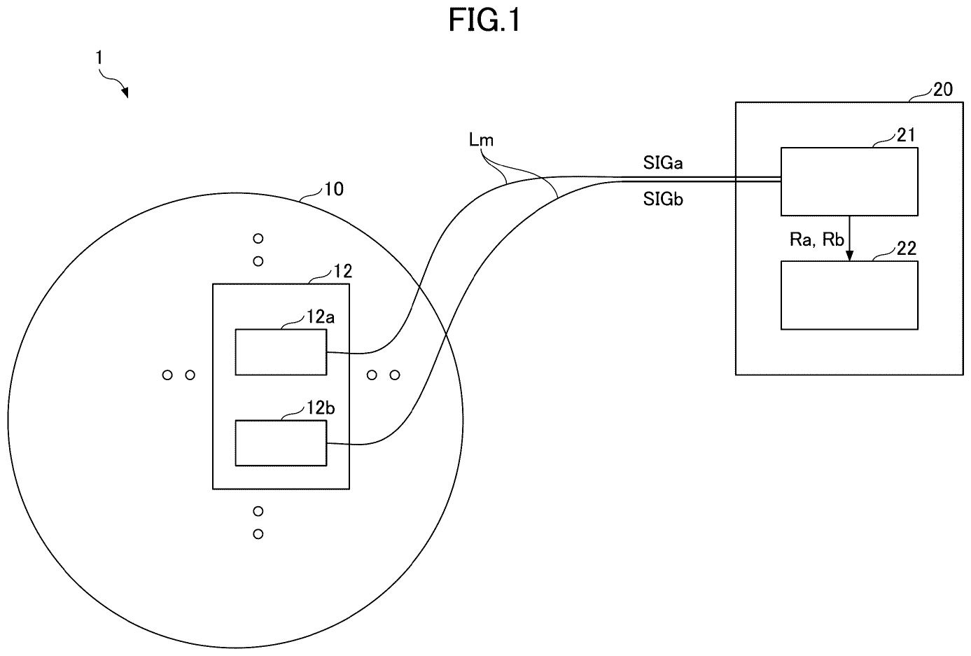

FIG. 1 is a diagram illustrating an overall configuration of an inspection system 1 as an example of the inspection system according to the first embodiment. An inspection system according to the first embodiment will be described using the inspection system 1 as an example.

An inspection system 1 includes a semiconductor substrate 10 and an inspection device 20.

### (Semiconductor Substrate 10)

The semiconductor substrate 10 is a substrate on which interconnect and circuit elements are formed. The semiconductor substrate 10 is formed with interconnects and circuit elements by performing a plurality of processes on a silicon substrate.

The semiconductor substrate 10 is not limited to a silicon substrate, and may be, for example, a silicon carbide substrate or a gallium arsenide substrate.

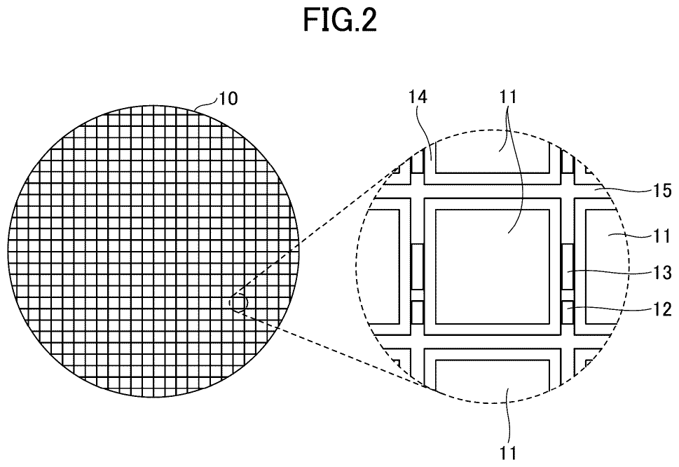

The structure of the semiconductor substrate 10 will be described. FIG. 2 is a diagram for explaining the semiconductor substrate 10 of the inspection system 1 as an example of the inspection system according to the present embodiment. The semiconductor substrate 10 has a substantially circular shape in a top view.

The semiconductor substrate 10 has a plurality of chips 11. Each of the plurality of chips 11 includes a desired circuit. Each chip 11 has a desired circuit, and by operating that circuit, each chip performs a desired function.

The semiconductor substrate 10 also includes a plurality of TEGs 12 and a plurality of TEGs 13 for process and device evaluation. The TEG 12 is used to evaluate process variation. The TEG 12 includes an inspection circuit for evaluating process variation. The TEG 13 is used to evaluate the device. The TEG 13 is used for electrical measurement of a threshold voltage of a transistor or the like performed in a wafer acceptance test (WAT).

The plurality of TEGs 12 are provided in the vicinity of the plurality of chips 11, respectively. Similarly, the plurality of TEGs 13 are provided in the vicinity of the plurality of chips 11, respectively. By inspecting each of the TEG 12 and the TEG 13, the state of the chip 11 located in the vicinity of each of the TEG 12 and the TEG 13 can be inspected.

The semiconductor substrate 10 has a plurality of chip forming regions 14 in which the plurality of chips 11 are respectively formed. After the plurality of chips 11 are formed, the semiconductor substrate 10 is cut into individual chips 11 by a dicing saw. The semiconductor substrate 10 has a cutting region 15, which is a region for cutting each of the plurality of chips 11, between the adjacent chip forming regions 14.

Each of the TEG 12 and the TEG 13 is formed in the cutting region 15. Either the TEG 12 or the TEG 13 may be formed in the chip forming region 14.

The details of the TEG 12 will be described. The TEG 12 has a plurality of inspection circuits having different variations in predetermined characteristics with respect to a predetermined type of process variation in processing the semiconductor substrate 10. The TEG 12 has an inspection circuit 12a and an inspection circuit 12b.

Process variation in the case of processing the semiconductor substrate 10 includes, for example, a variation in a concentration of ions doped in a semiconductor layer and a variation in a thickness of an oxide film. When an ion concentration and an oxide film thickness vary, for example, a threshold voltage of a metal-oxide semiconductor (MOS) transistor varies. A predetermined characteristic of the inspection circuit 12a varies when process variation occurs. Similarly, a predetermined characteristic of the inspection circuit 12b varies when process variation occurs. The characteristic values are, for example, a frequency, a voltage, a current, and the like.

The inspection circuits 12a and 12b differ in their sensitivity to process variation in certain characteristics. In other words, a magnitude of a variation of a characteristic with respect to process variation in one of the inspection circuits 12a and 12b differs from that of the other.

For example, a variation of a characteristic with respect to process variation in the inspection circuit 12b is made larger than a variation of a characteristic with respect to process variation in the inspection circuit 12a. By making a variation of a characteristic with respect to process variation in the inspection circuit 12b larger than a variation of a characteristic with respect to process variation in the inspection circuit 12a, process variation which could not be detected in a detection result in the inspection circuit 12a can be detected.

### (Inspection Device 20)

The inspection device 20 measures the characteristics of the inspection circuits 12a and 12b. The inspection device 20 estimates process variation when each of the inspection circuits 12a and 12b is formed, based on the measured characteristics of each of the inspection circuits 12a and 12b.

The inspection device 20 is provided with a measurer 21 and an estimator 22.

### (Measurer 21)

The measurer 21 measures the characteristics of the inspection circuits 12a and 12b. The measurer 21 is connected to each of the inspection circuits 12a and 12b in any one of the plurality of TEGs 12 by an interconnect Lm.

The measurer 21 supplies power to the inspection circuit 12a to be measured and detects a signal SIGa that is output from the inspection circuit 12a. The measurer 21 measures a predetermined characteristic from the signal SIGa. The measurer 21 supplies power to the inspection circuit 12b to be measured and detects a signal SIGb that is output from the inspection circuit 12b. The measurer 21 measures a predetermined characteristic from the signal SIGb.

The measurer 21 outputs, to the estimator 22, a measurement result Ra obtained by measuring the predetermined characteristic in the inspection circuit 12a and a measurement result Rb obtained by measuring the predetermined characteristic in the inspection circuit 12b.

The predetermined characteristic measured by the measurer 21 is, for example, a frequency, a voltage, and a current.

### (Estimator 22)

The estimator 22 estimates process variation when each of the inspection circuits 12a and 12b is formed. The estimator 22 estimates process variation based on the measurement results Ra and Rb measured by the measurer 21.

For example, the estimator 22 estimates a variation of an ion concentration and a variation of an oxide film thickness in a semiconductor process based on the measurement results Ra and Rb.

### <Inspection Method>

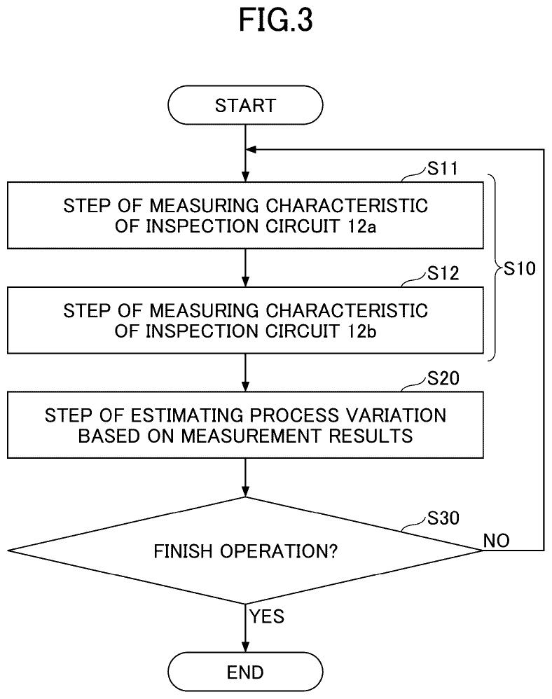

An inspection method using the inspection system according to the first embodiment will be described. FIG. 3 is a flowchart for explaining an inspection method using the inspection system 1 as the example of the inspection system according to the first embodiment. Each step of the inspection method will be described.

### (Step S10)

First, the inspection system 1 measures a predetermined characteristic of each of the inspection circuits 12a and 12b formed on the semiconductor substrate 10. Specifically, the measurer 21 measures a predetermined characteristic in each of the inspection circuits 12a and 12b formed on the semiconductor substrate 10.

The measurer 21 is connected to the inspection circuits 12a and 12b included in the TEG 12 to be inspected among the plurality of TEGs 12 formed on the semiconductor substrate 10 via the interconnects Lm. The measurer 21 measures the predetermined characteristic in each of the connected inspection circuits 12a and 12b.

### (Step S11)

First, the measurer 21 measures a characteristic of the inspection circuit 12a. The measurer 21 supplies the inspection circuit 12a with power necessary for operating the inspection circuit 12a. The measurer 21 detects a signal SIGa in the inspection circuit 12a. The measurer 21 measures a predetermined characteristic from the signal SIGa. The measurer 21 outputs a measurement result Ra, which is obtained by measuring the predetermined characteristic, to the estimator 22. When the measurement of the inspection circuit 12a is completed, the measurer 21 stops the supply of the electric power to the inspection circuit 12a.

### (Step S12)

Next, the measurer 21 measures a characteristic of the inspection circuit 12b. The measurer 21 supplies the inspection circuit 12b with power necessary for operating the inspection circuit 12b. The measurer 21 detects a signal SIGb in the inspection circuit 12b. The measurer 21 measures a predetermined characteristic from the signal SIGb. The measurer 21 outputs a measurement result Rb, which is obtained by measuring the predetermined characteristic, to the estimator 22. When the measurement of the inspection circuit 12b is completed, the measurer 21 stops the supply of the electric power to the inspection circuit 12b.

In the above description, the supply of power to the inspection circuit is stopped after the measurement of the inspection circuit is completed, but a separate power supply may be connected to the inspection circuit to continue the supply of power to the inspection circuit even when the inspection circuit is not measured.

### (Step S20)

Next, the inspection system 1 estimates process variation based on the measurement result Ra obtained by measuring the inspection circuit 12a and the measurement result Rb obtained by measuring the inspection circuit 12b. Specifically, the estimator 22 estimates process variation when the inspection circuits 12a and 12b are formed on the semiconductor substrate 10, based on the measurement results Ra and Rb.

The estimator 22 acquires the measurement result Ra obtained by measuring the inspection circuit 12a from the measurer 21. The estimator 22 acquires the measurement result Rb obtained by measuring the inspection circuit 12b from the measurer 21.

The inspection circuit 12a and the inspection circuit 12b differ in the magnitude of the variation of the predetermined characteristic with respect to specific process variation in a plurality of processes for processing the semiconductor substrate 10. Therefore, when the measurement result Ra is compared with the measurement result Rb, the variation can be observed with emphasis on specific process variation. By observing the variation with emphasis on specific process variation, it can be estimated that specific process variation has occurred.

### (Step S30)

Next, the inspection system 1 determines whether or not to finish the processing. Specifically, the estimator 22 determines whether or not to finish the processing. In the case where the processing is to be finished (Yes in step S30), the estimator 22 finishes the processing. In the case where the process is not finished, in other words, in the case where the processing is to be continued (No in step S30), the estimator 22 returns to step S10 and repeats the processing. For example, the inspection system 1 repeats the processing to inspect a plurality of TEGs 12 on the semiconductor substrate 10.

### SUMMARY

According to the inspection system of the first embodiment, it is possible to estimate process variation in a semiconductor process.

The inspection circuit 12a is an example of a first inspection circuit, and the inspection circuit 12b is an example of a second inspection circuit. The measurement result Ra is an example of a first measurement result, and the measurement result Rb is an example of a second measurement result.

### Second Embodiment

An inspection system according to the second embodiment will be described. The inspection system according to the second embodiment estimates process variation for a semiconductor substrate when a first inspection circuit and a second inspection circuit are formed on the semiconductor substrate. The inspection system according to the second embodiment estimates process variation by measuring characteristics in the first inspection circuit and the second inspection circuit having different variations in characteristics with respect to a process variation.

### <Inspection System>

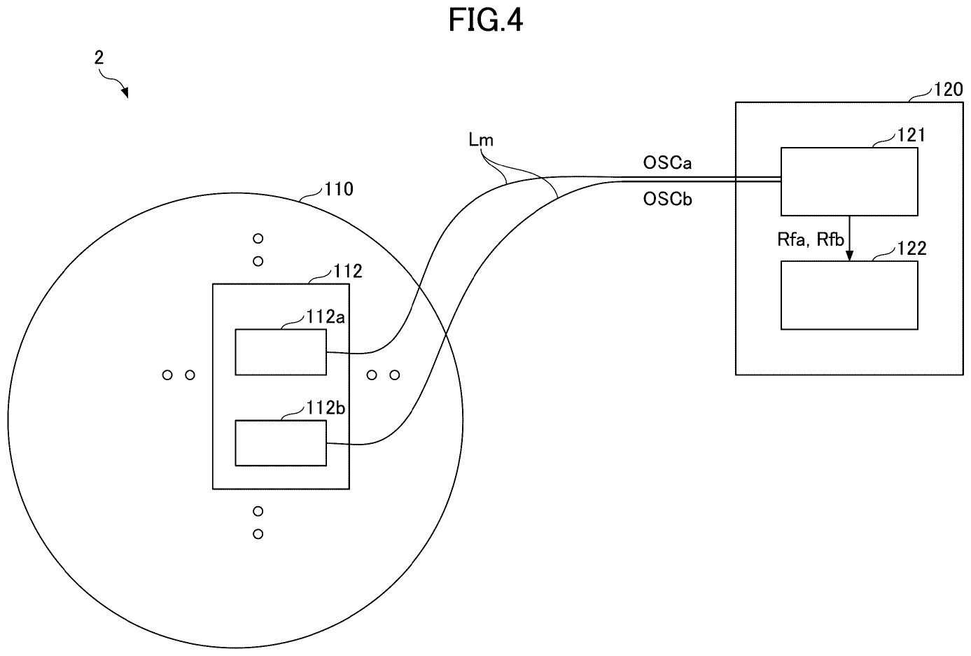

FIG. 4 is a diagram illustrating an overall configuration of an inspection system 2 as an example of the inspection system according to the second embodiment. An inspection system according to the second embodiment will be described using the inspection system 2 as an example.

An inspection system 2 includes a semiconductor substrate 110 and an inspection device 120.

### (Semiconductor Substrate 110)

The semiconductor substrate 110 is a substrate on which interconnect and circuit elements are formed. The semiconductor substrate 110 includes TEGs 112 instead of the TEGs 12 in the semiconductor substrate 10. Refer to the description of the semiconductor substrate 10 for the details of the semiconductor substrate 110 except for the TEGs 112, and the details of the TEG 112 will be described hereinafter.

The TEG 112 has a plurality of inspection circuits having different variations in predetermined characteristics with respect to a predetermined type of process variation in processing the semiconductor substrate 110. The TEG 112 has an inspection circuit 112a and an inspection circuit 112b.

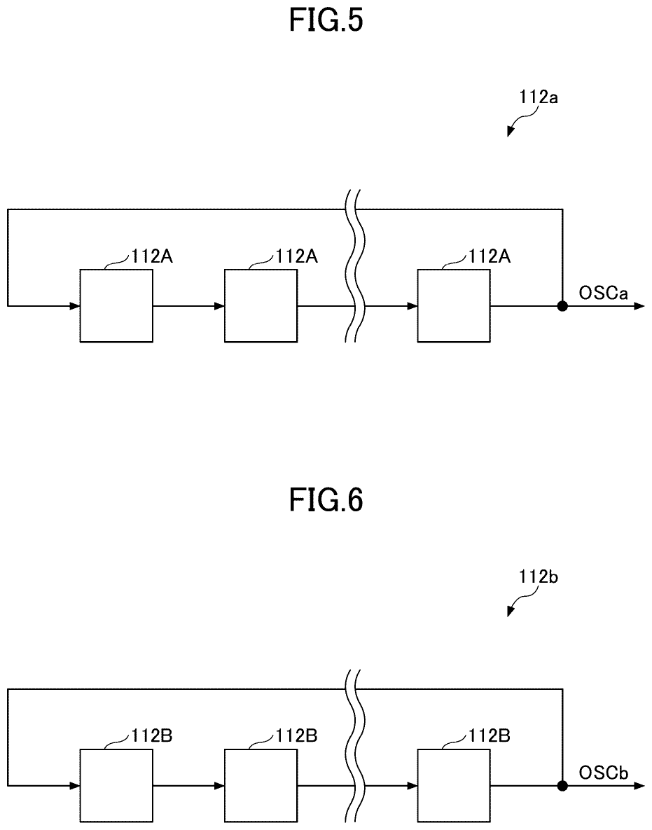

Each of the inspection circuits 112a and 112b will be described. FIG. 5 is a diagram for explaining the inspection circuit 112a of the inspection system 2 as an example of the inspection system according to the second embodiment. FIG. 6 is a diagram for explaining the inspection circuit 112b of the inspection system 2 as an example of the inspection system according to the second embodiment.

The inspection circuit 112a includes a plurality of element circuits 112A. The inspection circuit 112a includes an odd number of element circuits 112a. The plurality of element circuits 112A are connected in series.

Each of the plurality of element circuits 112A is a logic inverter. In the inspection circuit 112a, an output of the element circuit 112A at the final stage among the odd number of element circuits 112A is input to the element circuit 112A at the foremost stage. The inspection circuit 112a is a feedback oscillation circuit. The inspection circuit 112a is what is known as a ring oscillator (ring oscillation circuit). When power is supplied, the inspection circuit 112a outputs a signal OSCa which is an AC signal having a frequency caused by the delay in each of the element circuits 112A.

The inspection circuit 112b includes a plurality of element circuits 112B. The inspection circuit 112b includes an odd number of element circuits 112B. The plurality of element circuits 112B are connected in series.

Each of the plurality of element circuits 112B is a circuit of inverted logic. In the inspection circuit 112b, an output of the element circuit 112B at the end of the odd number of element circuits 112B is input to the element circuit 112B at the head. The inspection circuit 112b is a feedback oscillation circuit. The inspection circuit 112b is what is known as a ring oscillator (ring oscillation circuit). When power is supplied, the inspection circuit 112b outputs a signal OSCb which is an AC signal having a frequency caused by the delay in each of the element circuits 112B.

The element circuits 112A and 112B differ in the degree of influence of the variation in a frequency on process variation in the substrate processing process when the semiconductor substrate 110 is formed.

### (Inspection Device 120)

The inspection device 120 measures a frequency which is a predetermined characteristic in each of the inspection circuits 112a and 112b. The inspection device 120 estimates process variation when each of the inspection circuits 112a and 112b is formed, based on the measured characteristics of each of the inspection circuits 112a and 112b.

The inspection device 120 is provided with a measurer 121 and an estimator 122.

### (Measurer 121)

The measurer 121 measures the characteristics of the inspection circuits 112a and 112b. The measurer 121 is connected to each of the inspection circuits 112a and 112b in any one of the plurality of TEGs 112 by interconnects Lm.

The measurer 121 supplies power to the inspection circuit 112a to be measured and detects a signal OSCa that is output from the inspection circuit 112a. The measurer 121 measures a predetermined characteristic from the signal OSCa. The measurer 121 measures a frequency of the signal OSCa as a predetermined characteristic.

The measurer 121 supplies power to the inspection circuit 112b to be measured and detects a signal OSCb that is output from the inspection circuit 112b. The measurer 121 measures a predetermined characteristic from the signal OSCb. The measurer 121 measures a frequency of the signal OSCb as a predetermined characteristic.

The measurer 121 outputs, to the estimator 122, a measurement result Rfa obtained by measuring the frequency of the signal OSCa, which is a predetermined characteristic in the inspection circuit 112a, and a measurement result Rfb obtained by measuring the frequency of the signal OSCb, which is a predetermined characteristic in the inspection circuit 12b.

### (Estimator 122)

The estimator 122 estimates process variation when each of the inspection circuits 112a and 112b is formed. The estimator 122 estimates process variation based on the measurement results Rfa and Rfb measured by the measurer 121.

### SUMMARY

According to the inspection system of the second embodiment, it is possible to estimate process variation in a semiconductor process.

The plurality of element circuits 112A is an example of a plurality of first element circuits, the element circuit 112A is an example of a first element circuit, and the inspection circuit 112a is an example of a first inspection circuit. The plurality of element circuits 112B is an example of a plurality second first element circuits, the element circuit 112B is an example of a second element circuit, and the inspection circuit 112b is an example of a second inspection circuit.

### Third Embodiment

Next, an inspection system according to the third embodiment will be described. The inspection system according to the third embodiment is an inspection system having a more limited configuration for each of the element circuits 112A and 112B compared to the inspection system according to the second embodiment. The element circuits 112a and 112B are selected in such a manner that the inspection circuit 112a having the element circuit 112A and the inspection circuit 112b having the element circuit 112B have different sensitivities to process variation. In the inspection system according to the third embodiment, the element circuit 112A and the element circuit 112B are different in the function and the configuration of the circuit.

### <Element Circuit>

The element circuits respectively constituting the element circuits 112A and 112B will be described. As the element circuits, a NOT circuit, a NAND circuit, and a NOR circuit will be described.

### (NOT Circuit)

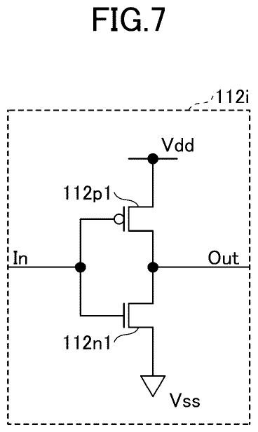

The NOT circuit is a logic NOT circuit. The NOT circuit is what is known as an inverter. FIG. 7 is a circuit diagram for explaining a NOT circuit as an example of the element circuit 112i included in the inspection circuit of the inspection system according to the third embodiment.

In the present disclosure, a p-type metal-oxide semiconductor field effect transistor (MOSFET) having a p-channel is referred to as a “PMOS transistor”. An n-type MOSFET having an n-channel is referred to as an “NMOS transistor”.

The NOT circuit 112i is a NOT circuit. The NOT circuit 112i includes a PMOS transistor 112p1 and an NMOS transistor 112n1.

Either one of the source or the drain of the PMOS transistor 112p1 is connected to a power supply potential Vdd. The other of the source or the drain of the PMOS transistor 112p1 is connected to either the source or the drain of the NMOS transistor 112n1 and to the output Out of the NOT circuit 112i. The other of the source or the drain of the NMOS transistor 112n1 is connected to a common potential Vss.

The gate of the PMOS transistor 112p1 and the gate of the NMOS transistor 112n1 are connected to the input In of the NOT circuit 112i.

### (NAND Circuit)

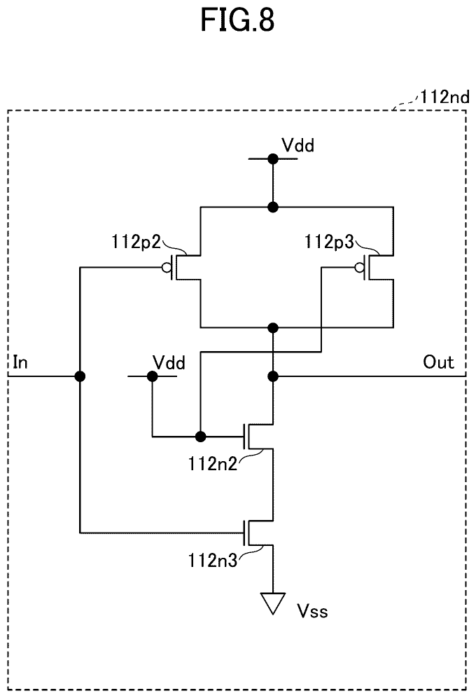

The NAND circuit is a NOT AND circuit. FIG. 8 is a circuit diagram for explaining a NAND circuit 112nd as an example of the element circuit included in the inspection circuit of the inspection system according to the third embodiment.

The NAND circuit 112nd is a NAND circuit. The NAND circuit 112nd includes a PMOS transistor 112p2 and a PMOS transistor 112p3, and an NMOS transistor 112n2 and an NMOS transistor 112n3.

Either one of the source or the drain of each of the PMOS transistor 112p2 and the PMOS transistor 112p3 is connected to the power supply potential Vdd. The other of the source or the drain of the PMOS transistor 112p2 and the PMOS transistor 112p3 is connected to either the source or the drain of the NMOS transistor 112n2 and to the output Out of the NAND circuit 112nd.

The other of the source or the drain of the NMOS transistor 112n2 is connected to either the source or the drain of the NMOS transistor 112n3.

The other of the source or the drain of the NMOS transistor 112n3 is connected to a common potential Vss. The gate of the PMOS transistor 112p2 and the gate of the NMOS transistor 112n3 are connected to the input In of the NAND circuit 112nd. The gate of the PMOS transistor 112p3 is connected to the gate of the NMOS transistor 112n2 and is connected to the power supply potential Vdd.

The NAND circuit 112nd includes an NMOS transistor 112n2 and an NMOS transistor 112n3 connected in series between the power supply potential Vdd and the common potential Vss. Therefore, the NAND circuit 112nd is strongly influenced by the n-channels of the NMOS transistor 112n2 and the NMOS transistor 112n3. Since the NAND circuit 112nd is strongly influenced by an n-channel, the NAND circuit 112nd is strongly influenced by an n-channel when the ion concentration of an n-channel varies. Therefore, by employing the NAND circuit 112nd as either the inspection circuit 112a or the inspection circuit 112b, it is possible to detect a variation in the ion concentration of an n-channel as process variation.

### (NOR Circuit)

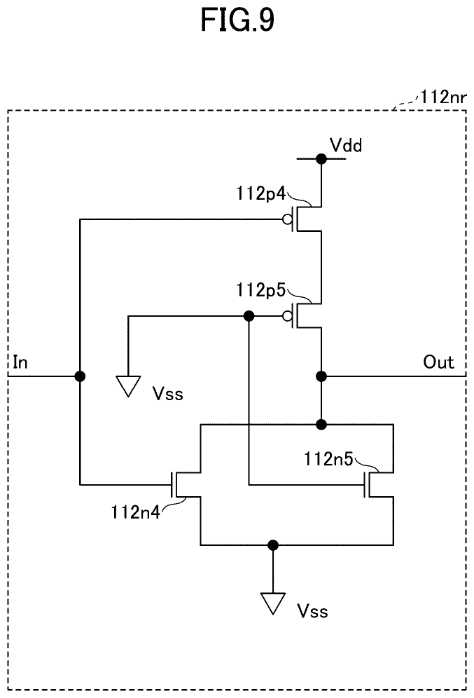

The NOR circuit is a Not OR circuit. FIG. 9 is a circuit diagram for explaining a NOR circuit 112nr as an example of the element circuit included in the inspection circuit of the inspection system according to the third embodiment.

The NOR circuit 112nr is a NOR circuit. The NOR circuit 112nr includes a PMOS transistor 112p4 and a PMOS transistor 112p5, and an NMOS transistor 112n4 and an NMOS transistor 112n5.

Either one of the source or the drain of the PMOS transistor 112p4 is connected to a power supply potential Vdd. The other of the source or the drain of the PMOS transistor 112p4 is connected to either the source or the drain of the PMOS transistor 112p5. The other of the source or the drain of the PMOS transistor 112p5 is connected to either the source or the drain of each of the NMOS transistor 112n4 and the NMOS transistor 112n5 and to the output Out of the NOR circuit 112nr.

The other of the source or the drain of each of the NMOS transistor 112n4 and the NMOS transistor 112n5 is connected to the common potential Vss. The gate of the PMOS transistor 112p4 and the gate of the NMOS transistor 112n4 are connected to the input In of the NOR circuit 112nr. The gate of the PMOS transistor 112p5 is connected to the gate of the NMOS transistor 112n5 and is connected to the common potential Vss.

The NOR circuit 112nr includes a PMOS transistor 112p4 and a PMOS transistor 112p5 connected in series between the power supply potential Vdd and the common potential Vss. Therefore, the NOR circuit 112nr is strongly influenced by the p-channels of the PMOS transistor 112p4 and the PMOS transistor 112p5. Since the NOR circuit 112nr is strongly influenced by a p-channel, the NOR circuit 112nr is strongly influenced by a p-channel when the ion concentration of a p-channel varies. Therefore, by employing the NOR circuit 112nr as either the inspection circuit 112a or the inspection circuit 112b, it is possible to detect a variation in the ion concentration of a p-channel as process variation.

### Examples of Combination of Element Circuits 112A and 112B

### First Combination Example

The inspection circuit 112A includes the NOT circuit 112i as the element circuit 112A. The inspection circuit 112b includes the NAND circuit 112nd as the element circuit 112B.

### Second Combination Example

The inspection circuit 112A includes the NOT circuit 112i as the element circuit 112A. The inspection circuit 112b includes the NOR circuit 112nr as the element circuit 112B.

### Third Combination Example

The inspection circuit 112A includes the NAND circuit 112nd as the element circuit 112A. The inspection circuit 112b includes the NOR circuit 112nr as the element circuit 112B.

In the above example, the circuit constituting the element circuit 112A and the circuit constituting the element circuit 112B may be replaced with each other.

### SUMMARY

According to the inspection system of the third embodiment, it is possible to estimate process variation in a semiconductor process. According to the inspection system of the third embodiment, when a variation in the ion concentration occurs, the variation in the ion concentration can be estimated.

The NOT circuit 112i is an example of a first element circuit, and the NAND circuit 112nd is an example of a second element circuit. The PMOS transistor 112p1 is an example of a first PMOS transistor, and the NMOS transistor 112n1 is an example of a first NMOS transistor. The PMOS transistor 112p2 is an example of a second PMOS transistor, and the PMOS transistor 112p3 is an example of a third PMOS transistor. The NMOS transistor 112n2 is an example of a second NMOS transistor, and the NMOS transistor 112n3 is an example of a third NMOS transistor.

The NOT circuit 112i is an example of a first element circuit, and the NOR circuit 112nr is an example of a second element circuit. The PMOS transistor 112p1 is an example of a first PMOS transistor, and the NMOS transistor 112n1 is an example of a first NMOS transistor. The PMOS transistor 112p4 is an example of a fourth PMOS transistor, and the PMOS transistor 112p5 is an example of a fifth PMOS transistor. The NMOS transistor 112n4 is an example of a fourth NMOS transistor, and the NMOS transistor 112n5 is an example of a fifth NMOS transistor.

### Fourth Embodiment

Next, an inspection system according to the fourth embodiment will be described. The inspection system according to the fourth embodiment is an inspection system having a more limited configuration for each of the element circuits 112A and 112B compared to the inspection system according to the second embodiment. The element circuits 112A and 112B are selected in such a manner that the inspection circuit 112a having the element circuit 112A and the inspection circuit 112b having the element circuit 112B have different sensitivities to process variation. In the inspection system according to the fourth embodiment, the element circuits 112A and 112B have the same function but have different circuit configurations.

### <Element Circuit>

The element circuits respectively constituting the element circuits 112A and 112B will be described. As the element circuits, a NOT circuit to which dummy circuits are connected (a NOT circuit with dummy circuits) and a NOT circuit to which dummy interconnects are connected (a NOT circuit with dummy interconnects) will be described.

(NOT Circuit with Dummy Circuits)

The NOT circuit with dummy circuits includes a NOT circuit and two dummy NOT circuits connected to the input but not to the output. In other words, the NOT circuit with dummy circuits includes a NOT circuit and two dummy NOT circuits connected to the input but having no output destination. The NOT circuit with dummy circuits can increase the apparent size of the gate capacitance in the element circuit by dividing the input into a plurality of inputs and connecting the inputs to a plurality of NOT circuits. By increasing the gate capacitance in the element circuit, a variation in the insulating film thickness can be estimated.

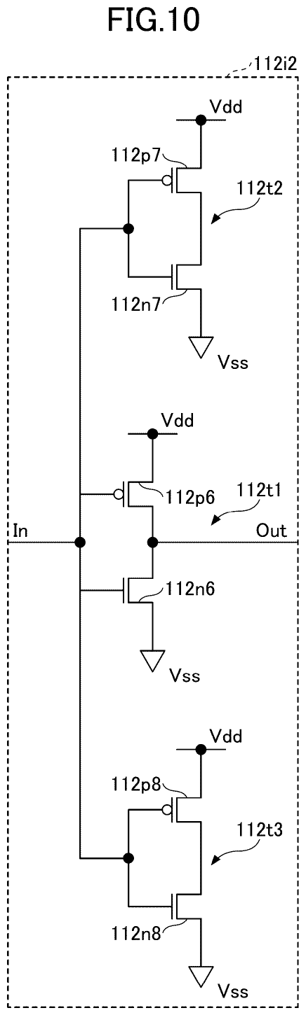

The NOT circuit with the dummy circuit will be described with reference to FIG. 10. FIG. 10 is a circuit diagram for explaining a NOT circuit 112i2 as an example of the element circuit included in the inspection circuit of the inspection system according to the fourth embodiment.

The NOT circuit 112i2 includes a NOT circuit 112t1, a dummy NOT circuit 112t2, and a dummy NOT circuit 112t3.

The NOT circuit 112t1 is a NOT circuit. The NOT circuit 112t1 includes a PMOS transistor 112p6 and an NMOS transistor 112n6.

Either one of the source or the drain of the PMOS transistor 112p6 is connected to a power supply potential Vdd. The other of the source or the drain of the PMOS transistor 112p6 is connected to either the source or the drain of the NMOS transistor 112n6 and to the output Out of the NOT circuit 112i2. The other of the source or the drain of the NMOS transistor 112n6 is connected to a common potential Vss. The gate of the PMOS transistor 112p6 and the gate of the NMOS transistor 112n6 are connected to the input In of the NOT circuit 112i2.

The dummy NOT circuit 112t2 is a NOT circuit. The dummy NOT circuit 112t2 is connected to the input In of the NOT circuit 112i2 but is not connected to the output Out of the NOT circuit 11212. In other words, the dummy NOT circuit 112t2 is a circuit having no output destination. The dummy NOT circuit 112t2 includes a PMOS transistor 112p7 and an NMOS transistor 112n7.

Either one of the source or the drain of the PMOS transistor 112p7 is connected to a power supply potential Vdd. The other of the source or the drain of the PMOS transistor 112p7 is connected to either the source or the drain of the NMOS transistor 112n7. The other of the source or the drain of the NMOS transistor 112n7 is connected to a common potential Vss. The gate of the PMOS transistor 112p7 and the gate of the NMOS transistor 112n7 are connected to the input In of the NOT circuit 112i2.

The dummy NOT circuit 112t3 is a NOT circuit. The dummy NOT circuit 112t3 is connected to the input In of the NOT circuit 112i2, but is not connected to the output Out of the NOT circuit 112i2. In other words, the dummy NOT circuit 112t3 is a circuit having no output destination. The dummy NOT circuit 112t3 includes a PMOS transistor 112p8 and an NMOS transistor 112n8.

Either one of the source or the drain of the PMOS transistor 112p8 is connected to a power supply potential Vdd. The other of the source or the drain of the PMOS transistor 112p8 is connected to either the source or the drain of the NMOS transistor 112n8. The other of the source or the drain of the NMOS transistor 112n8 is connected to a common potential Vss. The gate of the PMOS transistor 112p8 and the gate of the NMOS transistor 112n8 are connected to the input In of the NOT circuit 112i2.

(NOT Circuit with Dummy Interconnects)

A NOT circuit with dummy interconnects is provided with a NOT circuit and interconnects connected to the gate of the NOT circuit. The NOT circuit with dummy interconnects is a circuit for removing the influence of interconnects in the NOT circuit with dummy circuits.

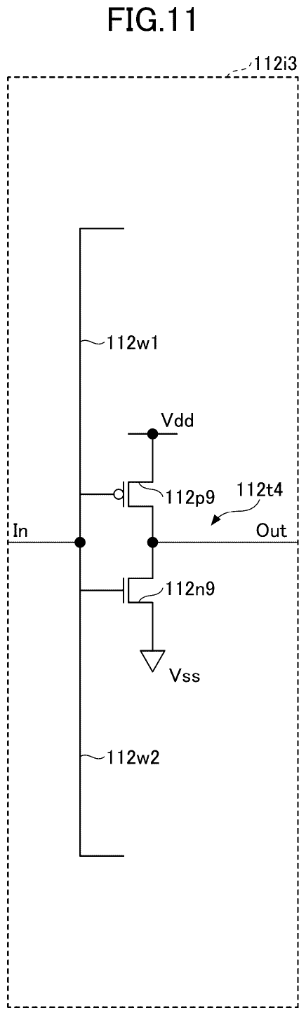

The NOT circuit with dummy interconnects will be described with reference to FIG. 11. FIG. 11 is a circuit diagram for explaining the NOT circuit 112i3 as an example of the element circuit included in the inspection circuit of the inspection system according to the fourth embodiment.

The NOT circuit 112i3 includes a NOT circuit 112t4, a dummy interconnect 112w1, and a dummy interconnect 112w2.

The NOT circuit 112t4 is a NOT circuit. The NOT circuit 112t4 includes a PMOS transistor 112p9 and an NMOS transistor 112n9.

Either one of the source or the drain of the PMOS transistor 112p9 is connected to a power supply potential Vdd. The other of the source or the drain of the PMOS transistor 112p9 is connected to either the source or the drain of the NMOS transistor 112n9 and to the output Out of the NOT circuit 112i3. The other of the source or the drain of the NMOS transistor 112n9 is connected to a common potential Vss. The gate of the PMOS transistor 112p9 and the gate of the NMOS transistor 112n9 are connected to the input In of the NOT circuit 112i3.

The dummy interconnect 112w1 has the same configuration as the interconnect from the input In to the dummy NOT circuit 112t2 in the NOT circuit 112i2.

The dummy interconnect 112w2 has the same configuration as the interconnect from the input In to the dummy NOT circuit 112t3 in the NOT circuit 112i2.

### Examples of Combination of Element Circuits 112A and 112B

### First Combination Example

The inspection circuit 112A includes the NOT circuit 112i2 with dummy circuits as the element circuit 112A. The inspection circuit 112b includes the NOT circuit 112i3 with dummy interconnects as the element circuit 112B.

### Second Combination Example

The inspection circuit 112A includes the NOT circuit 112i2 with dummy circuits as the element circuit 112A. The inspection circuit 112b includes the NOT circuit 112i as the element circuit 112B.

In the above example, the circuit constituting the element circuit 112A and the circuit constituting the element circuit 112B may be replaced with each other.

### SUMMARY

According to the inspection system of the fourth embodiment, it is possible to estimate process variation in a semiconductor process. According to the inspection system of the fourth embodiment, when a variation in the insulating film thickness occurs, the variation in the insulating film thickness can be estimated.

The NOT circuit 112i2 is an example of a first element circuit, and the NOT circuit 112i3 is an example of a second element circuit. The dummy NOT circuit 112t2 is an example of a first dummy NOT circuit, and the dummy NOT circuit 112t3 is an example of a second dummy NOT circuit. The dummy interconnect 112w1 is an example of a first dummy interconnect, and the dummy interconnect 112w2 is an example of a second dummy interconnect.

The PMOS transistor 112p6 is an example of a sixth PMOS transistor, and the NMOS transistor 112n6 is an example of a sixth NMOS transistor. The PMOS transistor 112p7 is an example of a seventh PMOS transistor, the PMOS transistor 112p8 is an example of an eighth PMOS transistor, and the PMOS transistor 112p9 is an example of a ninth PMOS transistor. The nMOS transistor 112n7 is an example of a seventh NMOS transistor, the NMOS transistor 112n8 is an example of an eighth NMOS transistor, and the NMOS transistor 112n9 is an example of a ninth NMOS transistor.

In the above example, the element circuit is configured by using a NOT circuit, but a NAND circuit or a NOR circuit may be employed instead of a NOT circuit.

### Fifth Embodiment

An inspection system according to the fifth embodiment will be described. The inspection system according to the fifth embodiment is an inspection system having a more limited configuration for each of the element circuits 112A and 112B compared to the inspection system according to the second embodiment. The element circuits 112A and 112B are selected in such a manner that the inspection circuit 112a having the element circuit 112A and the inspection circuit 112b having the element circuit 112B have different sensitivities to process variation. In the inspection system according to the fifth embodiment, the element circuits 112A and 112B have the same function and circuit configuration but have different circuit shapes.

### <Element Circuit>

The element circuits respectively constituting the element circuits 112A and 112B will be described. As the element circuits, a NOT circuit, a NAND circuit, and a NOR circuit will be described.

### (NOT Circuit)

A case where a NOT circuit is used as an element circuit constituting each of the element circuits 112A and 112B will be described. A NOT circuit is selected as one of the element circuits 112A and 112B from four types of NOT circuits having different dimensions constituting a MOS transistor. The element circuits 112A and 112B are selected so as to be of different types of NOT circuits.

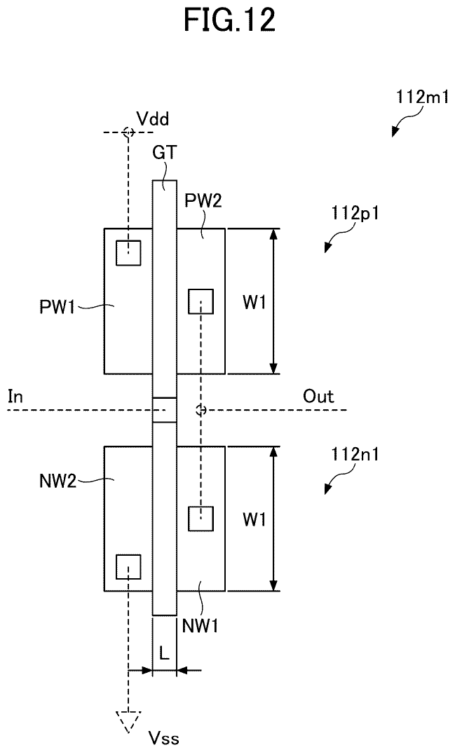

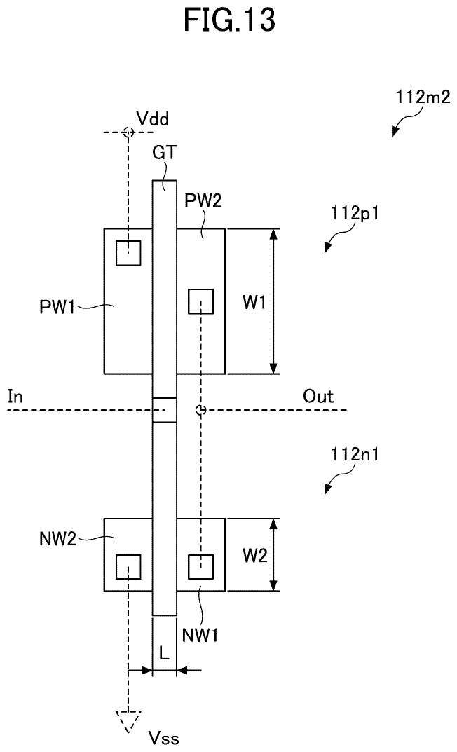

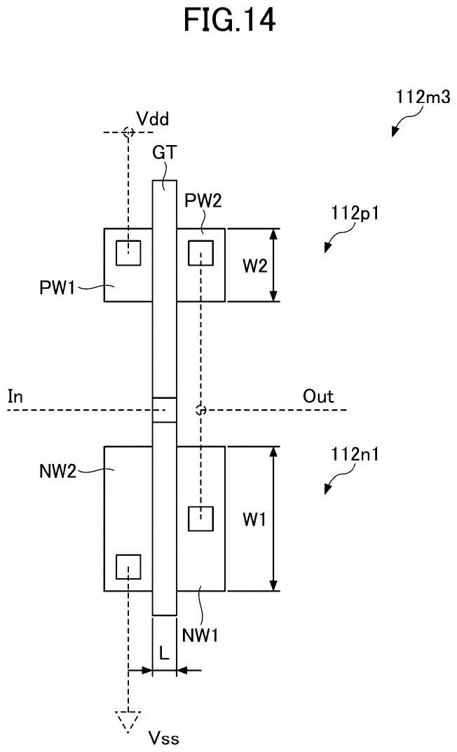

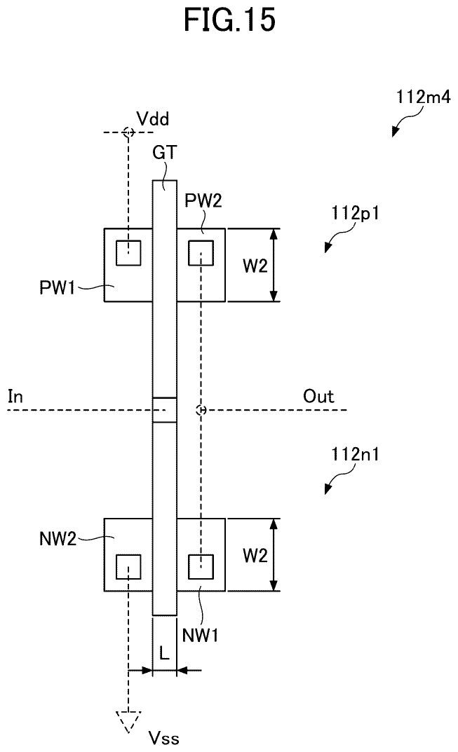

FIG. 12 is a diagram for explaining the structure of the NOT circuit 112m1 as an example of the element circuit included in the inspection circuit of the inspection system according to the fifth embodiment. FIG. 13 is a diagram for explaining the structure of the NOT circuit 112m2 as an example of the element circuit included in the inspection circuit of the inspection system according to the fifth embodiment. FIG. 14 is a diagram for explaining the structure of the NOT circuit 112m3 as an example of the element circuit included in the inspection circuit of the inspection system according to the fifth embodiment. FIG. 15 is a diagram for explaining the structure of the NOT circuit 112m4 as an example of the element circuit included in the inspection circuit of the inspection system according to the fifth embodiment.

In FIGS. 12 through 15, the gate electrode of the MOS transistor and the semiconductor layer are viewed from the top surface of the layer. In FIGS. 12 through 15, dotted lines indicate electrical connections. In FIGS. 12 through 15, the semiconductor layers (diffusion layers) constituting the source and drain of the MOS transistor in the periphery of the gate electrode are illustrated, and the other semiconductor layers are omitted.

Each of the NOT circuits 112m1, 112m2, 112m3, and 112m4 has the same element configuration as the NOT circuit 112i illustrated in FIG. 7. The gate width of the PMOS transistor 112p1 or the NMOS transistor 112n1 is different among the NOT circuits 112m1, 112m2, 112m3, and 112m4.

### (NOT Circuit 112m1)

The NOT circuit 112m1 includes a gate electrode GT. The gate electrode GT is provided across the PMOS transistor 112p1 and the NMOS transistor 112n1. A dimension L of the gate electrode GT corresponds to the gate length of each of the PMOS transistor 112p1 and the NMOS transistor 112n1. A dimension W1 corresponds to the gate width of each of the PMOS transistor 112p1 and the NMOS transistor 112n1.

The semiconductor layer PW1 is a semiconductor layer serving as either the source or the drain of the PMOS transistor 112p1. The semiconductor layer PW2 is a semiconductor layer serving as the other of the source or the drain of the PMOS transistor 112p1. The semiconductor layer NW1 is a semiconductor layer serving as either the source or the drain of the NMOS transistor 112n1. The semiconductor layer NW2 is a semiconductor layer serving as the other of the source or the drain of the NMOS transistor 112n1.

### (NOT Circuit 112m2)

The NOT circuit 112m2 differs from the NOT circuit 112m1 in that the gate width of the NMOS transistor 112n1 is a dimension W2. In other words, the gate width of the NMOS transistor 112n1 in the NOT circuit 112m2 differs from the gate width of the NMOS transistor 112n1 in the NOT circuit 112m1.

### (NOT Circuit 112m3)

The NOT circuit 112m3 differs from the NOT circuit 112m1 in that the gate width of the PMOS transistor 112p1 is the dimension W2. In other words, the gate width of the PMOS transistor 112p1 in the NOT circuit 112m3 differs from the gate width of the PMOS transistor 112p1 in the NOT circuit 112m1.

### (NOT Circuit 112m4)

The NOT circuit 112m4 differs from the NOT circuit 112m1 in that the gate width of each of the NMOS transistor 112n1 and the PMOS transistor 112p1 is the dimension W2. In other words, the gate width of the NMOS transistor 112n1 in the NOT circuit 112m4 differs from the gate width of the NMOS transistor 112n1 in the NOT circuit 112m1. In other words, the gate width of the PMOS transistor 112p1 in the NOT circuit 112m4 differs from the gate width of the PMOS transistor 112p1 in the NOT circuit 112m1.

A variable that determines the driving capability of the MOS transistor is a drain current Id. The drain current Id is proportional to a gate oxide film capacitance Cox per unit area. The drain current Id in the linear region of the MOS transistor is illustrated in Expression 1. The drain current Id in the saturation region of the MOS transistor is illustrated in Expression 2.

$$[ Expression 1 ]$$

$$Id = \frac{Wg}{Lg} μ Cox \{ ( Vg - Vt ) Vd - \frac{1}{2} {Vd}^{2} \} \qquad Expression 1$$

$$[ Expression 2 ]$$

$$Id = \frac{Wg}{2 Lg} μ Co {x ( Vg - Vt )}^{2} \qquad Expression 2$$

Lg is a gate length, Wg is a gate width, μ is mobility of electrons or holes, Vg is a gate-source voltage, Vd is a drain-source voltage, and Vt is a threshold voltage.

Therefore, by changing the size of the gate width Wg, for example, a variation of the gate oxide film capacitance Cox in process variation can be varied.

The gate length Lg is a particularly important parameter for the configuration of a transistor and is a dimension that is strictly controlled. Therefore, it is generally difficult to change the gate length Lg, which is strictly controlled in size. Therefore, in the inspection device according to the present embodiment, a variation of a characteristic with respect to process variation is made different by changing the gate width Wg.

### Examples of Combination of Element Circuits 112A and 112B

### First Combination Example

The inspection circuit 112A includes the NOT circuit 112m1 as the element circuit 112A. The inspection circuit 112b includes the NOT circuit 112m2 as the element circuit 112B.

### Second Combination Example

The inspection circuit 112A includes the NOT circuit 112m1 as the element circuit 112A. The inspection circuit 112b includes the NOT circuit 112m3 as the element circuit 112B.

### Third Combination Example

The inspection circuit 112A includes the NOT circuit 112m1 as the element circuit 112A. The inspection circuit 112b includes the NOT circuit 112m4 as the element circuit 112B.

### Other Combination Examples

The combination of the element circuits 112A and 112B is not limited to the above examples, and two circuits may be selected as appropriate from the NOT limited to the above example circuit 112m1, the NOT circuit 112m2, the NOT circuit 112m3, and the NOT circuit 112m4. In the above example, the circuit constituting the element circuit 112A and the circuit constituting the element circuit 112B may be replaced with each other.

### (NAND Circuit)

A case where a NAND circuit is used as an element circuit constituting each of the element circuits 112A and 112B will be described. A NAND circuit is selected as one of the element circuits 112A and 112B from four types of NAND circuits having different dimensions constituting a MOS transistor. The element circuits 112A and 112B are selected so as to be of different types of NAND circuits.

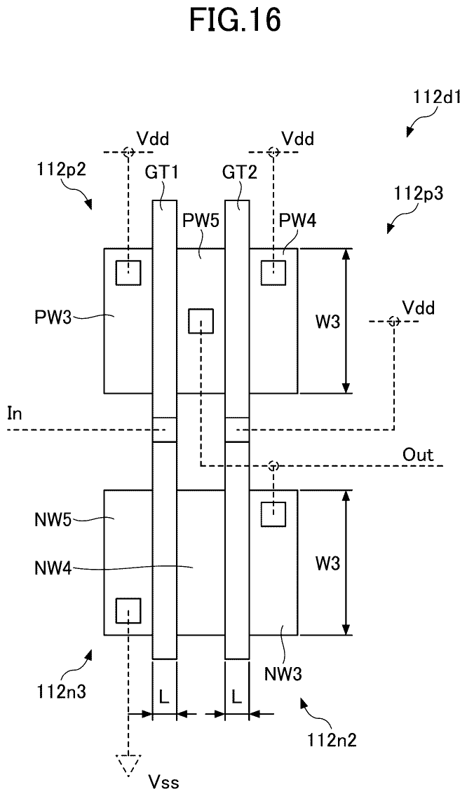

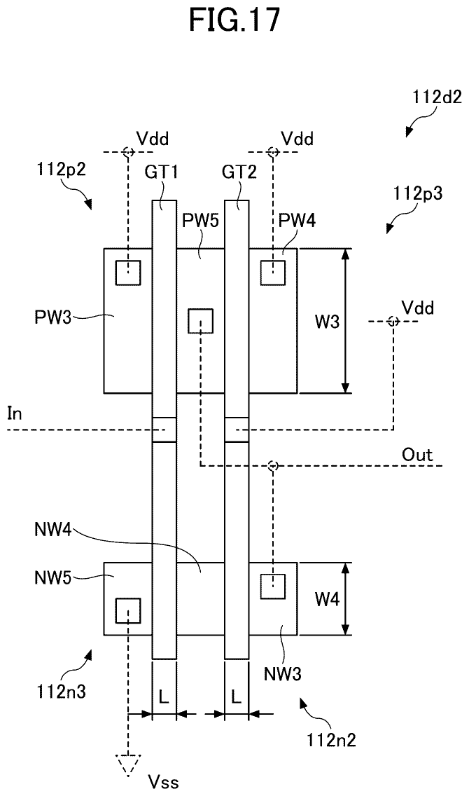

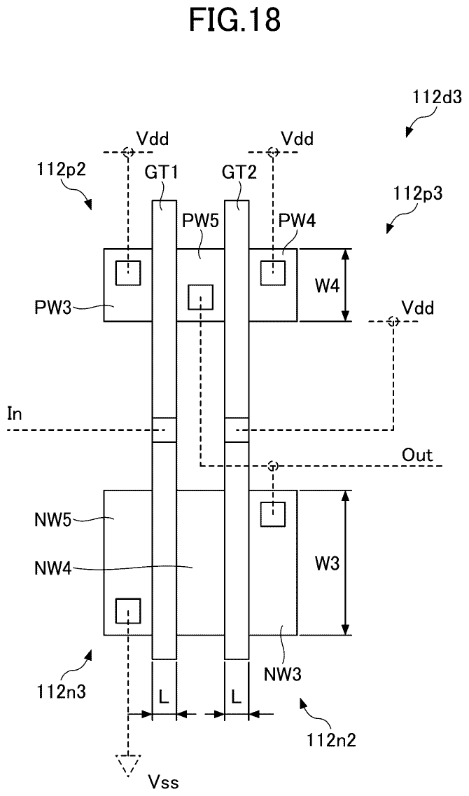

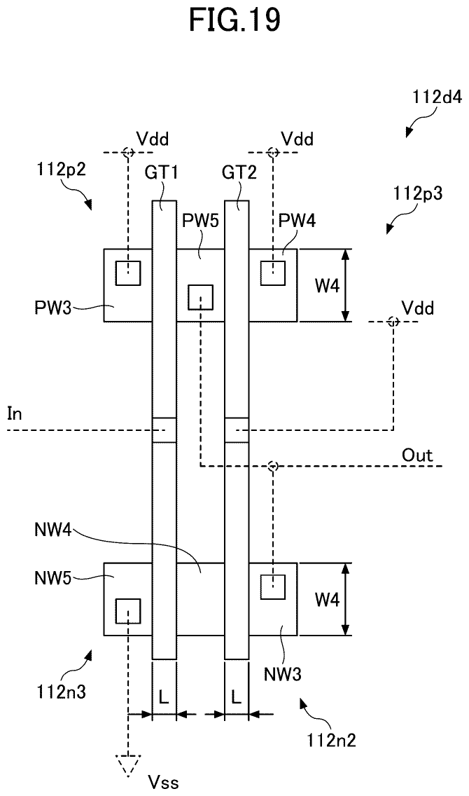

FIG. 16 is a diagram for explaining the structure of the NAND circuit 112d1 as an example of the element circuit included in the inspection circuit of the inspection system according to the fifth embodiment. FIG. 17 is a diagram for explaining the structure of the NAND circuit 112d2 as an example of the element circuit included in the inspection circuit of the inspection system according to the fifth embodiment. FIG. 18 is a diagram for explaining the structure of the NAND circuit 112d3 as an example of the element circuit included in the inspection circuit of the inspection system according to the fifth embodiment. FIG. 19 is a diagram for explaining the structure of the NAND circuit 112d4 as an example of the element circuit included in the inspection circuit of the inspection system according to the fifth embodiment.

In FIGS. 16 through 19, the gate electrode of the MOS transistor and the semiconductor layer are viewed from the top surface of the layer. In FIGS. 16 through 19, dotted lines indicate electrical connections. In FIGS. 16 through 19, the semiconductor layers (diffusion layers) constituting the source and drain of the MOS transistor in the periphery of the gate electrode are illustrated, and the other semiconductor layers are omitted.

Each of the NAND circuits 112d1, 112d2, 112d3, and 112d4 has the same element configuration as the NAND circuit 112nd illustrated in FIG. 8. The NAND circuits 112d1, 112d2, 112d3, and 112d4 have different gate widths in the PMOS transistor, which is a p-type transistor, or the NMOS transistor, which is an n-type transistor.

### (NAND Circuit 112d1)

The NAND circuit 112d1 includes a gate electrode GT1 and a gate electrode GT2. The gate electrode GT1 is provided across the PMOS transistor 112p2 and the NMOS transistor 112n3. The gate electrode GT2 is provided across the PMOS transistor 112p3 and the NMOS transistor 112n2. The dimension L of the gate electrodes GT1 and GT2 corresponds to the gate length of each of the PMOS transistor 112p2, the PMOS transistor 112p3, the NMOS transistor 112n2, and the NMOS transistor 112n3. A dimension W3 corresponds to the gate width of each of the PMOS transistor 112p2, the PMOS transistor 112p3, the NMOS transistor 112n2, and the NMOS transistor 112n3.

The semiconductor layer PW3 is a semiconductor layer serving as either the source or the drain of the PMOS transistor 112p2. The semiconductor layer PW4 is a semiconductor layer serving as either the source or the drain of the PMOS transistor 112p3. The semiconductor layer PW5 is a semiconductor layer which serves as the other of the source or the drain of the PMOS transistor 112p2 and the other of the source or the drain of the PMOS transistor 112p3.

The semiconductor layer NW3 is a semiconductor layer serving as either the source or the drain of the NMOS transistor 112n2. The semiconductor layer NW4 is a semiconductor layer which serves as the other of the source or the drain of the NMOS transistor 112n2 and either one of the source or the drain of the NMOS transistor 112n3. The semiconductor layer NW5 is a semiconductor layer serving as the other of the source or the drain of the NMOS transistor 112n3.

### (NAND Circuit 112d2)

The NAND circuit 112d2 differs from the NAND circuit 112d1 in that the gate width of each of the NMOS transistor 112n2 and the NMOS transistor 112n3 is a dimension W4. In other words, the gate width of the NMOS transistor 112n2 in the NAND circuit 112d2 differs from the gate width of the NMOS transistor 112n2 in the NAND circuit 112d1. In other words, the gate length of the NMOS transistor 112n3 in the NAND circuit 112d2 differs from the gate length of the NMOS transistor 112n3 in the NAND circuit 112d1.

### (NAND Circuit 112d3)

The NAND circuit 112d3 differs from the NAND circuit 112d1 in that the gate width of each of the PMOS transistor 112p2 and the PMOS transistor 112p3 is the dimension W4. In other words, the gate width of the PMOS transistor 112p2 in the NAND circuit 112d3 differs from the gate width of the PMOS transistor 112p2 in the NAND circuit 112d1. The gate width of the PMOS transistor 112p3 in the NAND circuit 112d3 differs from the gate width of the PMOS transistor 112p3 in the NAND circuit 112d1.

### (NAND Circuit 112d4)

The NAND circuit 112d4 differs from NAND circuit 112d1 in that the gate width of each of the NMOS transistor 112n2 and the NMOS transistor 112n3 is the dimension W4. The NAND circuit 112d4 differs from the NAND circuit 112d1 in that the gate width of each of the PMOS transistor 112p2 and the PMOS transistor 112p3 is the dimension W4.

In other words, the gate width of the NMOS transistor 112n2 in the NAND circuit 112d4 differs from the gate width of the NMOS transistor 112n2 in the NAND circuit 112d1. The gate width of the NMOS transistor 112n3 in the NAND circuit 112d4 differs from the gate width of the NMOS transistor 112n3 in the NAND circuit 112d1.

Furthermore, the gate width of the PMOS transistor 112p2 in the NAND circuit 112d4 differs from the gate width of the PMOS transistor 112p2 in the NAND circuit 112d1. The gate width of the PMOS transistor 112p3 in the NAND circuit 112d4 differs from the gate width of the PMOS transistor 112p3 in the NAND circuit 112d1.

### Examples of Combination of Element Circuits 112A and 112B

### First Combination Example

The inspection circuit 112a includes the NAND circuit 112d1 as the element circuit 112A. The inspection circuit 112b includes the NAND circuit 112d2 as the element circuit 112B.

### Second Combination Example

The inspection circuit 112a includes the NAND circuit 112d1 as the element circuit 112A. The inspection circuit 112b includes the NAND circuit 112d3 as the element circuit 112B.

### Third Combination Example

The inspection circuit 112a includes the NAND circuit 112d1 as the element circuit 112A. The inspection circuit 112b includes the NAND circuit 112d4 as the element circuit 112B.

### Other Combination Examples

The combination of the element circuits 112A and 112B is not limited to the above examples, and two circuits may be selected as appropriate from the NAND circuit 112d1, the NAND circuit 112d2, the NAND circuit 112d3, and the NAND circuit 112d4. In the above example, the circuit constituting the element circuit 112A and the circuit constituting the element circuit 112B may be replaced with each other.

### (NOR Circuit)

A case where a NOR circuit is used as an element circuit constituting each of the element circuits 112A and 112B will be described. A NOR circuit is selected as one of the element circuits 112A and 112B from four types of NOR circuits having different dimensions constituting a MOS transistor. The element circuits 112A and 112B are selected so as to be of different types of NOR circuits.

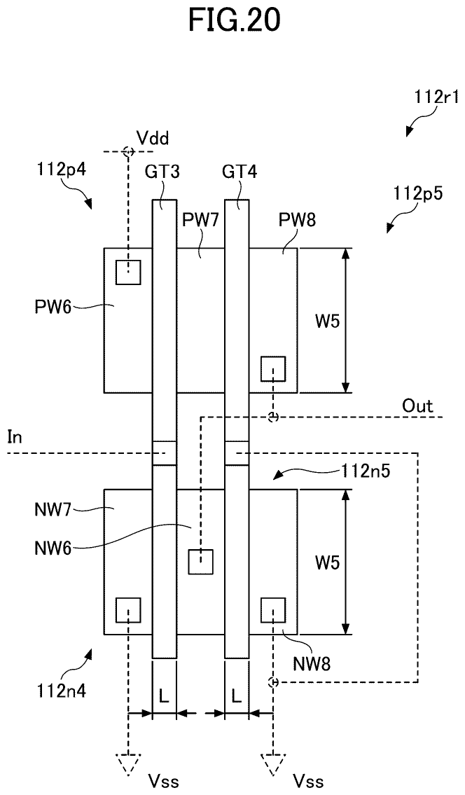

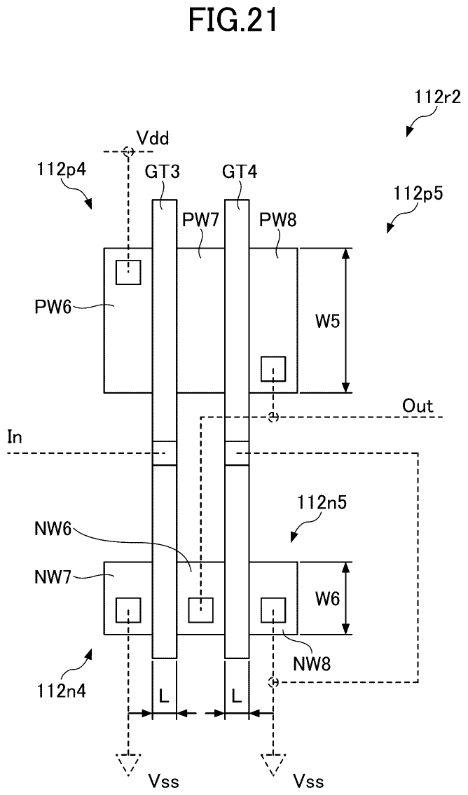

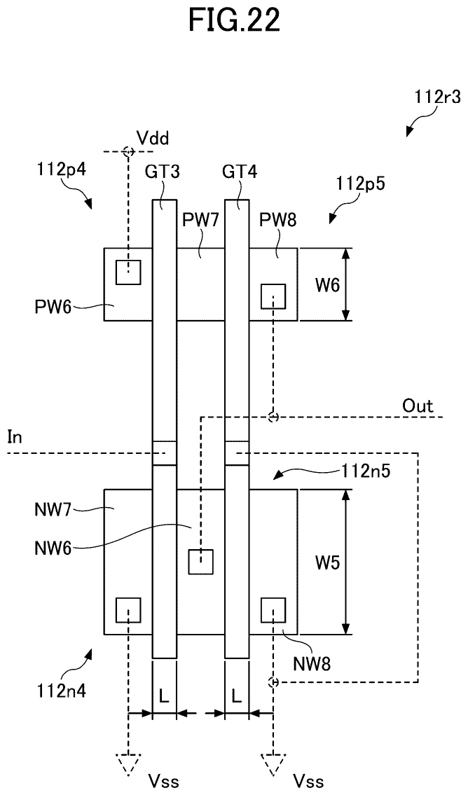

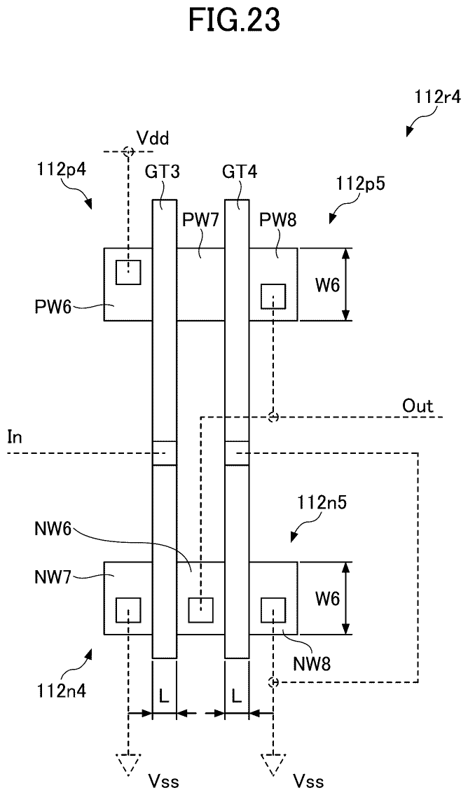

FIG. 20 is a diagram for explaining the structure of the NOR circuit 112r1 as an example of the element circuit included in the inspection circuit of the inspection system according to the fifth embodiment. FIG. 21 is a diagram for explaining the structure of the NOR circuit 112r2 as an example of the element circuit included in the inspection circuit of the inspection system according to the fifth embodiment. FIG. 22 is a diagram for explaining the structure of the NOR circuit 112r3 as an example of the element circuit included in the inspection circuit of the inspection system according to the fifth embodiment. FIG. 23 is a diagram for explaining the structure of the NOR circuit 112r4 as an example of the element circuit included in the inspection circuit of the inspection system according to the fifth embodiment.

In FIGS. 20 through 23, the gate electrode of the MOS transistor and the semiconductor layer are viewed from the top surface of the layer. In FIGS. 20 through 23, dotted lines indicate electrical connections. In FIGS. 20 through 23, the semiconductor layers (diffusion layers) constituting the source and drain of the MOS transistor in the periphery of the gate electrode are illustrated, and the other semiconductor layers are omitted.

Each of the NOR circuits 112r1, 112r2, 112r3, and 112r4 has the same element configuration as the NOR circuit 112nr illustrated in FIG. 9. The NOR circuits 112r1, 112r2, 112r3, and 112r4 have different gate widths in the PMOS transistor, which is a p-type transistor, or the NMOS transistor, which is an n-type transistor.

### (NOR Circuit 112r1)

The NOR circuit 112r1 includes a gate electrode GT3 and a gate electrode GT4. The gate electrode GT3 is provided across the PMOS transistor 112p4 and the NMOS transistor 112n4. The gate electrode GT4 is provided across the PMOS transistor 112p5 and the NMOS transistor 112n5. The dimension L of the gate electrodes GT3 and GT4 corresponds to the gate length of each of the PMOS transistor 112p4, the PMOS transistor 112p5, the NMOS transistor 112n4, and the NMOS transistor 112n5. A dimension W5 corresponds to the gate width of each of the PMOS transistor 112p4, the PMOS transistor 112p5, the NMOS transistor 112n4, and the NMOS transistor 112n5.

The semiconductor layer PW6 is a semiconductor layer serving as either the source or the drain of the PMOS transistor 112p4. The semiconductor layer PW7 is a semiconductor layer which serves as the other of the source ort the drain of the PMOS transistor 112p4 and either one of the source or the drain of the PMOS transistor 112p5. The semiconductor layer PW8 is a semiconductor layer serving as the other of the source or the drain of the PMOS transistor 112p5.

The semiconductor layer NW6 is a semiconductor layer which serves as either one of the source or the drain of the NMOS transistor 112n4 and either one of the source or the drain of the NMOS transistor 112n5. The semiconductor layer NW7 is a semiconductor layer serving as the other of the source or the drain of the NMOS transistor 112n4. The semiconductor layer NW8 is a semiconductor layer serving as the other of the source or the drain of the NMOS transistor 112n5.

### (NOR Circuit 112r2)

The NOR circuit 112r2 differs from the NOR circuit 112r1 in that the gate width of each of the NMOS transistor 112n4 and the NMOS transistor 112n5 is a dimension W6. In other words, the gate width of the NMOS transistor 112n4 in the NOR circuit 112r2 differs from the gate width of the NMOS transistor 112n4 in the NOR circuit 112r1. In other words, the gate width of the NMOS transistor 112n5 in the NOR circuit 112r2 differs from the gate width of the NMOS transistor 112n5 in the NOR circuit 112r1.

### (NOR Circuit 112r3)

The NOR circuit 112r3 differs from the NOR circuit 112r1 in that the gate width of each of the PMOS transistor 112p4 and the PMOS transistor 112p5 is the dimension W6. In other words, the gate width of the PMOS transistor 112p4 in the NOR circuit 112r3 differs from the gate width of the PMOS transistor 112p4 in the NOR circuit 112r1. In other words, the gate width of the PMOS transistor 112p5 in the NOR circuit 112r3 differs from the gate width of the PMOS transistor 112p5 in the NOR circuit 112r1.

### (NOR Circuit 112r4)

The NOR circuit 112r4 differs from the NOR circuit 112r1 in that the gate length of each of the NMOS transistor 112n4 and the NMOS transistor 112n5 is the dimension W6. The NOR circuit 112r4 differs from the NOR circuit 112r1 in that the gate width of each of the PMOS transistor 112p4 and the PMOS transistor 112p5 is the dimension W6.

In other words, the gate width of the NMOS transistor 112n4 in the NOR circuit 112r4 differs from the gate width of the NMOS transistor 112n4 in the NOR circuit 112r1. The gate width of the NMOS transistor 112n5 in the NOR circuit 112r4 differs from the gate width of the NMOS transistor 112n5 in the NOR circuit 112r1.

Furthermore, the gate width of the PMOS transistor 112p4 in the NOR circuit 112r4 differs from the gate width of the PMOS transistor 112p4 in the NOR circuit 112r1. The gate width of the PMOS transistor 112p5 in the NOR circuit 112r4 differs from the gate width of the PMOS transistor 112p5 in the NOR circuit 112r1.

### Examples of Combination of Element Circuits 112A and 112B

### First Combination Example

The inspection circuit 112a includes the NOR circuit 112r1 as the element circuit 112A. The inspection circuit 112b includes the NOR circuit 112r2 as the element circuit 112B.

### Second Combination Example

The inspection circuit 112a includes the NOR circuit 112r1 as the element circuit 112A. The inspection circuit 112b includes the NOR circuit 112r3 as the element circuit 112B.

### Third Combination Example

The inspection circuit 112a includes a NOR circuit 112r1 as the element circuit 112A. The inspection circuit 112b includes a NOR circuit 112r4 as the element circuit 112B.

### Other Combination Examples

The combination of the element circuits 112A and 112B is not limited to the above examples, and two circuits may be selected as appropriate from the NOR circuit 112r1, the NOR circuit 112r2, the NOR circuit 112r3, and the NOR circuit 112r4. In the above example, the circuit constituting the element circuit 112A and the circuit constituting the element circuit 112B may be replaced with each other.

### SUMMARY

According to the inspection system of the fifth embodiment, it is possible to estimate process variation in a semiconductor process. According to the inspection system of the fifth embodiment, when a variation in the insulating film thickness occurs, the variation in the insulating film thickness can be estimated.

The NOT circuit 112m1 is an example of a first element circuit, and the NOT circuit 112m2 is an example of a second element circuit. The PMOS transistor 112p1 in the NOT circuit 112m1 is an example of a tenth PMOS transistor, and the NMOS transistor 112nl is an example of a tenth NMOS transistor. The PMOS transistor 112p1 in the NOT circuit 112m2 is an example of an eleventh PMOS transistor, and the NMOS transistor 112n1 is an example of an eleventh NMOS transistor.

### Sixth Embodiment

Next, an inspection system according to the sixth embodiment will be described. The inspection system according to the sixth embodiment includes three types of inspection circuits in the TEG in the semiconductor substrate.

### <Inspection System>

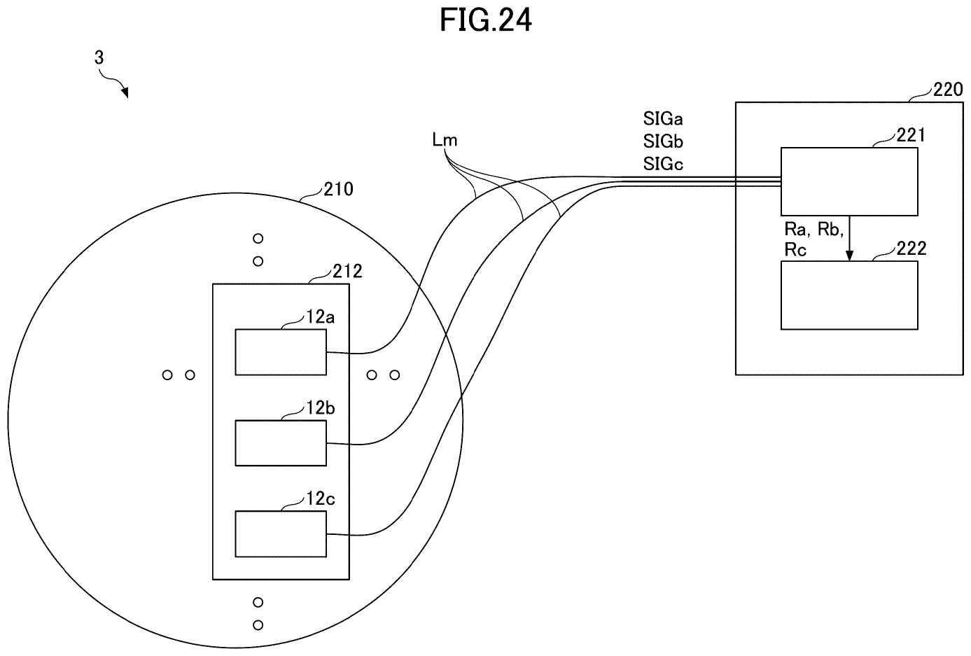

Herein, the inspection system according to the sixth embodiment will be described with respect to differences from the inspection system according to the first embodiment. FIG. 24 is a diagram illustrating an overall configuration of an inspection system 3 as an example of the inspection system according to the sixth embodiment. The inspection system according to the sixth embodiment will be described using the inspection system 3 as an example.

An inspection system 3 includes a semiconductor substrate 210 and an inspection device 220.

### (Semiconductor Substrate 210)

The semiconductor substrate 210 has a TEG 212 in place of the TEG 12 of the semiconductor substrate 10. The TEG 212 has an inspection circuit 12a, an inspection circuit 12b, and an inspection circuit 12c.

The inspection circuits 12a, 12b, and 12c have different sensitivities to process variation in a predetermined characteristic. In other words, a variation of a characteristic with respect to process variation in any of the inspection circuits 12a, 12b, and 12c differs from a variation of a characteristic with respect to process variation in the other inspection circuits among the inspection circuits 12a, 12b, and 12c.

### (Inspection Device 220)

The inspection device 220 measures the characteristics of the inspection circuits 12a, 12b, and 12c. The inspection device 220 estimates process variation when each of the inspection circuits 12a, 12b, and 12c is formed, based on the measured characteristics of each of the inspection circuits 12a, 12b, and 12c.

The inspection device 220 is provided with a measurer 221 and an estimator 222.

### (Measurer 221)

The measurer 221 measures the characteristics of the inspection circuits 12a, 12b, and 12c. The measurer 221 is connected to each of the inspection circuits 12a, 12b, and 12c in any one of the plurality of TEGs 212 by interconnects Lm.

The measurer 221 supplies power to the inspection circuit 12a to be measured and detects a signal SIGa that is output from the inspection circuit 12a. The measurer 221 measures a predetermined characteristic from the signal SIGa. The measurer 221 supplies power to the inspection circuit 12b to be measured and detects a signal SIGb that is output from the inspection circuit 12b. The measurer 221 measures a predetermined characteristic from the signal SIGb. The measurer 221 supplies power to the inspection circuit 12c to be measured and detects a signal SIGc that is output from the inspection circuit 12c. The measurer 221 measures a predetermined characteristic from the signal SIGc.

The measurer 221 outputs, to the estimator 222, a measurement result Ra obtained by measuring a predetermined characteristic in the inspection circuit 12a, a measurement result Rb obtained by measuring a predetermined characteristic in the inspection circuit 12b, and a measurement result Rc obtained by measuring a predetermined characteristic in the inspection circuit 12c.

### (Estimator 222)

The estimator 222 estimates process variation when each of the inspection circuits 12a, 12b, and 12c is formed. The estimator 222 estimates process variation based on the measurement results Ra, Rb, and Rc measured by the measurer 221.

### SUMMARY

According to the inspection system of the sixth embodiment, it is possible to estimate process variation in a semiconductor process.

The inspection circuit 12a is an example of a first inspection circuit, the inspection circuit 12b is an example of a second inspection circuit, and the inspection circuit 12c is an example of a third inspection circuit. The measurement result Ra is an example of a first measurement result, the measurement result Rb is an example of a second measurement result, and the measurement result Rc is an example of a third measurement result.

In the above example, the semiconductor substrate having three inspection circuits having different characteristics is described, but the number of inspection circuits is not limited to three, and the semiconductor substrate may have four or more inspection circuits having different characteristics.

### Seventh Embodiment

An inspection system according to the seventh embodiment will be described. The inspection system according to the seventh embodiment estimates process variation for a semiconductor substrate when a first inspection circuit, a second inspection circuit, and a third inspection circuit are formed on the semiconductor substrate. The inspection system according to the seventh embodiment estimates process variation by measuring characteristics in the first inspection circuit, the second inspection circuit, and the third inspection circuit having different variations in characteristics with respect to a process variation.

### <Inspection System>

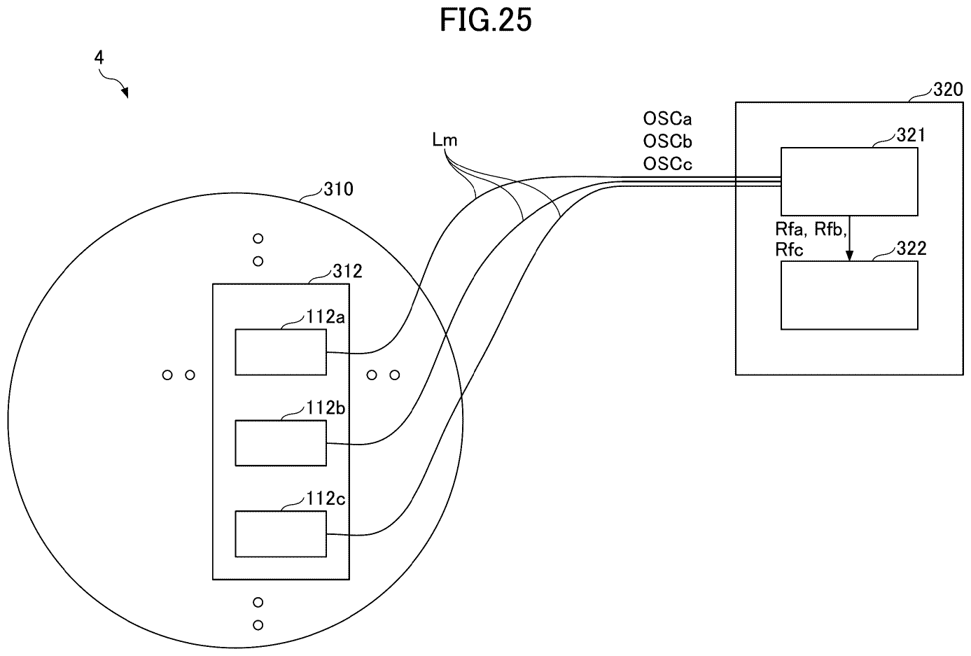

FIG. 25 is a diagram illustrating an overall configuration of an inspection system 4 as an example of the inspection system according to the seventh embodiment. An inspection system according to the seventh embodiment will be described using the inspection system 4 as an example.

An inspection system 4 includes a semiconductor substrate 310 and an inspection device 320.

### (Semiconductor Substrate 310)

The semiconductor substrate 310 is a substrate on which interconnect and circuit elements are formed. The semiconductor substrate 310 includes TEGs 312 instead of the TEGs 212 in the semiconductor substrate 210. Refer to the description of the semiconductor substrate 210 for the details of the semiconductor substrate 310 except for the TEGs 312, and the details of the TEG 312 will be described hereinafter.

The TEG 312 has a plurality of inspection circuits having different variations in predetermined characteristics with respect to a predetermined type of process variation in processing the semiconductor substrate 310. The TEG 312 has an inspection circuit 112a, an inspection circuit 112b, and an inspection circuit 112c.

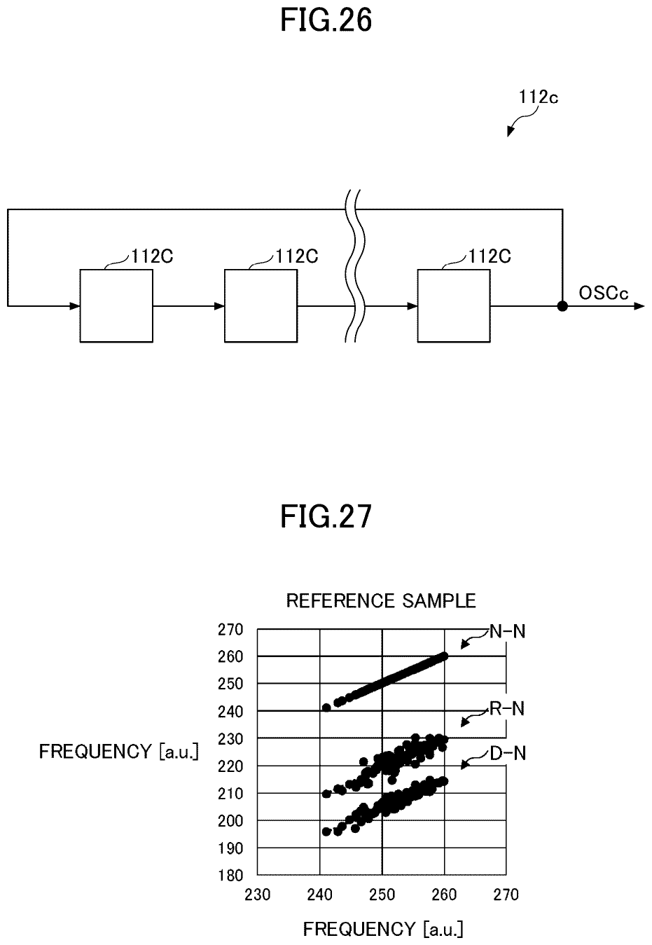

Refer to the description of the inspection system according to the second embodiment for each of the inspection circuits 112a and 112b, and the inspection circuit 112c will be described hereinafter. FIG. 26 is a diagram for explaining the inspection circuit 112c of the inspection system 4 as an example of the inspection system according to the seventh embodiment.

The inspection circuit 112c includes a plurality of element circuits 112C. The inspection circuit 112c includes an odd number of element circuits 112C. The plurality of element circuits 112C are connected in series.

Each of the plurality of element circuits 112C is a circuit of inverted logic. In the inspection circuit 112c, an output of the element circuit 112C at the final stage among the odd number of element circuits 112C is input to the element circuit 112C at the foremost stage. The inspection circuit 112c is a feedback oscillation circuit. The inspection circuit 112c is what is known as a ring oscillator (ring oscillation circuit). When power is supplied, the inspection circuit 112c outputs a signal OSCc which is an AC signal having a frequency caused by the delay in each of the element circuits 112C.

### (Inspection Device 320)

The inspection device 320 measures the predetermined characteristics of the inspection circuits 112a, 112b, and 112c. The inspection device 320 estimates process variation when each of the inspection circuits 112a, 112b, and 112c is formed, based on the measured characteristics of each of the inspection circuits 112a, 112b, and 112c.

The inspection device 320 is provided with a measurer 321 and an estimator 322.

### (Measurer 321)

The measurer 321 measures the characteristics of the inspection circuits 112a, 112b, and 112c. The measurer 321 is connected to each of the inspection circuits 112a and 112c in any one of the plurality of TEGs 312 by interconnects Lm.

The measurer 321 performs the same processing as that of the inspection system 2, which is an example of the inspection system according to the second embodiment, on the inspection circuits 112a and 112b. The measurer 321 supplies power to the inspection circuit 112c to be measured and detects a signal OSCc that is output from the inspection circuit 112c. The measurer 321 measures a predetermined characteristic from the signal OSCc. The measurer 321 measures a frequency of the signal OSCc as a predetermined characteristic.

The measurer 321 outputs, to the estimator 322, a measurement result Rfa obtained by measuring the frequency of the signal OSCa, which is a predetermined characteristic in the inspection circuit 112a, and a measurement result Rfb obtained by measuring the frequency of the signal OSCb, which is a predetermined characteristic in the inspection circuit 112b. Further, the measurer 321 outputs, to the estimator 322, the measurement result Rfc, which is obtained by measuring the frequency of the signal OSCc, which is a predetermined characteristic in the inspection circuit 112c.

### (Estimator 322)

The estimator 322 estimates process variation when each of the inspection circuits 112a, 112b, and 112c is formed. The estimator 322 estimates process variation based on the measurement results Rfa, Rfb, and Rfc measured by the measurer 321.

### Example of Combination of Element Circuits 112A, 112B, and 112C

### First Combination Example

The inspection circuit 112A includes the NOT circuit 112i as the element circuit 112A. The inspection circuit 112b includes the NAND circuit 112nd as the element circuit 112B. The inspection circuit 112c includes the NOR circuit 112nr as the element circuit 112C.

### Second Combination Example

The inspection circuit 112a includes the NOT circuit 112i as the element circuit 112A. The inspection circuit 112b includes the NOT circuit 11212 as the element circuit 112B. The inspection circuit 112c includes the NOT circuit 112i3 as the element circuit 112C.

### Third Combination Example

The inspection circuit 112a includes the NOT circuit 112m1 as the element circuit 112A. The inspection circuit 112b includes the NOT circuit 112m2 as the element circuit 112B. The inspection circuit 112c includes the NOT circuit 112m3 as the element circuit 112C.

### Other Combination Examples

The combination of the element circuits 112A, 112B, and 112C is not limited to the above examples, and three circuits may be selected as appropriate from the NOT circuit 112m1, the NOT circuit 112m2, the NOT circuit 112m3, and the NOT circuit 112m4. The combination of the element circuits 112A, 112B, and 112C is not limited to the above examples, and three circuits may be selected as appropriate from the NAND circuit 112d1, the NAND circuit 112d2, the NAND circuit 112d3, and the NAND circuit 112d4. The combination of the element circuits 112A, 112B, and 112C is not limited to the above examples, and three circuits may be selected as appropriate from the NOR circuit 112r1, the NOR circuit 112r2, the NOR circuit 112r3, and the NOR circuit 112r4.

In the above example, the circuit constituting the element circuit 112A, the circuit constituting the element circuit 112B, and the circuit constituting the element circuit 112C may be replaced with each other.

### SUMMARY

According to the inspection system of the seventh embodiment, it is possible to estimate process variation in a semiconductor process.

The plurality of element circuits 112A is an example of a plurality of first element circuits, the element circuit 112A is an example of a first element circuit, and the inspection circuit 112a is an example of a first inspection circuit. The plurality of element circuits 112B is an example of a plurality of second element circuits, the element circuit 112B is an example of a second element circuit, and the inspection circuit 112b is an example of a second inspection circuit. The plurality of element circuits 112C is an example of a plurality of third element circuits, the element circuit 112C is an example of a third element circuit, and the inspection circuit 112c is an example of a third inspection circuit.

### Operation Example 1

Operation Example 1 where the inspection device according to the present embodiment is operated will be described. Specifically, a case where the element circuits 112A, 112B, and 112C include a NOT circuit 112i, a NAND circuit 112nd, and a NOR circuit 112nr, respectively in the seventh embodiment will be described.

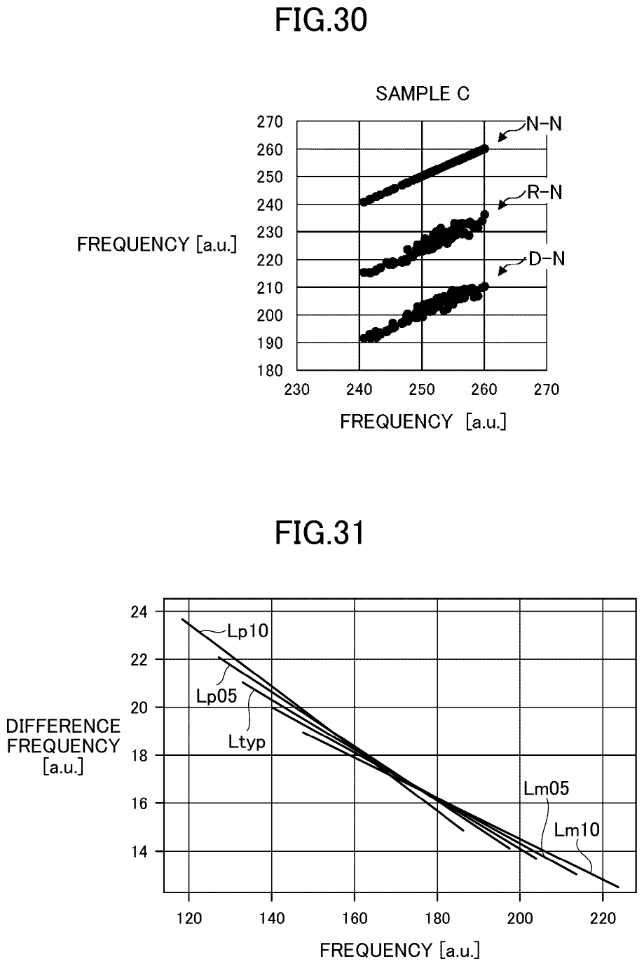

FIGS. 27, 28, 29, and 30 illustrate the results of measuring the frequencies of the outputs of the inspection circuits 112a, 112b, and 112c for the reference sample, sample A, sample B, and sample C, respectively. The horizontal axis in each of FIGS. 27, 28, 29, and 30 indicates the measurement results (frequencies) in the inspection circuit 112a. The vertical axis in each of FIGS. 27, 28, 29, and 30 illustrates the measurement results of the inspection circuits 112a, 112b, and 112c, respectively. The frequency is expressed in an arbitrary unit. The dots in FIGS. 27, 28, 29, and 30 are the results of measuring the inspection circuits 112a, 112b, and 112c of the plurality of TEGs 312 in one semiconductor substrate 310.

In FIGS. 27, 28, 29, and 30, data N-N indicates the measurement result of the inspection circuit 112a. Data D-N indicates the measurement result of the inspection circuit 112b. Data R-N indicates the measurement result of the inspection circuit 112c.

The reference sample is a semiconductor substrate 310 prepared under normal process conditions. Sample A is a semiconductor substrate 310 prepared under the same conditions as the reference sample. Sample B is a semiconductor substrate 310 formed under the condition that the threshold voltage of the NMOS transistor is lowered and the threshold voltage of the PMOS transistor is raised. Sample C is a semiconductor substrate 310 formed under the condition that the threshold voltage of the NMOS transistor is raised and the threshold voltage of the PMOS transistor is lowered. In other words, each of Sample A, Sample B, and Sample C is a sample in which the process conditions are modulated with respect to an ion concentration with respect to the reference sample.

Table 1 summarizes the difference between the average frequencies of the inspection circuits 112a and 112b, the difference between the average frequencies of the inspection circuits 112a and 112c, and the difference between the average frequencies of the inspection circuits 112b and 112c. The average frequency is an average of frequencies measured by a plurality of TEGs 312 in one semiconductor substrate 310. In Table 1, the inspection circuits 112a, 112b, and 112c are referred to as “inspection circuit a”, “inspection circuit b”, and “inspection circuit c”, respectively.

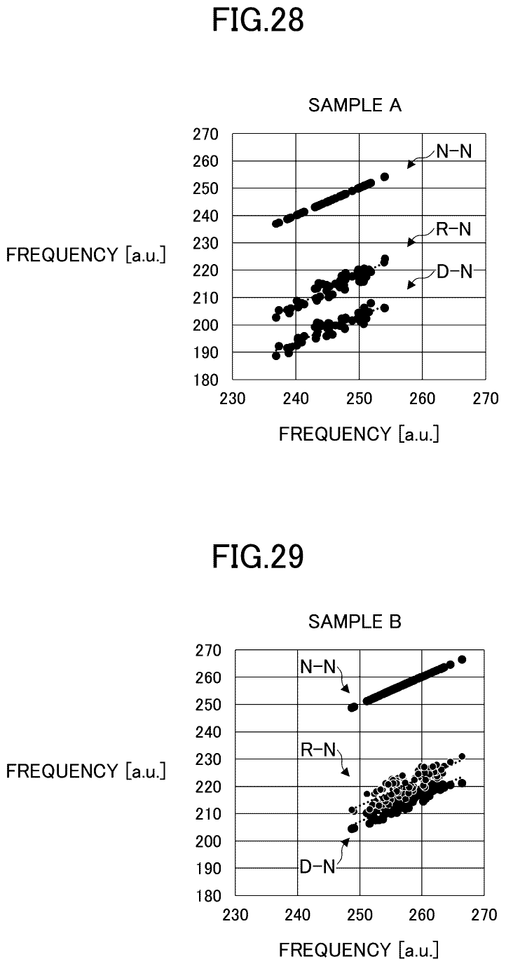

From FIGS. 27 and 28 and Table 1, substantially the same results are obtained for the reference sample and Sample A. Therefore, when the semiconductor substrate 310 is prepared under the same conditions, a good reproducibility is obtained.

TABLE 1

| | Reference | | | |
|---|---|---|---|---|
| | sample | Sample A | Sample B | Sample C |
| Difference in average | 45.2 | 46.7 | 42.9 | 48.8 |
| frequency between | | | | |
| inspection circuit a and | | | | |
| inspection circuit b | | | | |
| (Difference ΔF1) | | | | |
| Difference in average | 30.4 | 32.2 | 37.0 | 25.6 |
| frequency between | | | | |
| inspection circuit a and | | | | |
| inspection circuit c | | | | |
| (Difference ΔF2) | | | | |
| Difference in average | 14.8 | 14.5 | 6.0 | 23.2 |
| frequency between | | | | |
| inspection circuit b and | | | | |
| inspection circuit c | | | | |
| (Difference ΔF3) | | | | |

### (Comparison Between NOT Circuit and NAND Circuit)

The difference (difference ΔF1) between the average frequencies of the inspection circuit 112a in which the element circuit 112A is a NOT circuit and the inspection circuit 112b in which the element circuit 112B is a NAND circuit is compared. The difference ΔF1 is substantially equal between the reference sample and Sample A. On the other hand, the difference ΔF1 of Sample B is smaller than that of the reference sample. The smaller difference ΔF1 means that the frequency in Sample B is increased, that is, the threshold voltage is decreased. The difference ΔF1 of Sample C is larger than that of the reference sample. The larger difference ΔF1 means that the frequency in Sample C is decreased, that is, the threshold voltage is increased.

In other words, by comparing the difference (difference ΔF1) between the average frequencies of the inspection circuit 112a in which the element circuit 112A is a NOT circuit and the inspection circuit 112b in which the element circuit 112B is a NAND circuit, a variation of the ion concentration of the n-channel can be estimated.

### (Comparison Between NOT Circuit and NOR Circuit)

The difference (difference ΔF2) between the average frequencies of the inspection circuit 112a in which the element circuit 112A is a NOT circuit and the inspection circuit 112c in which the element circuit 112C is a NOR circuit is compared. The difference ΔF2 is substantially equal between the reference sample and Sample A. On the other hand, the difference ΔF2 of Sample B is larger than that of the reference sample. The larger difference ΔF2 means that the frequency in Sample B is decreased, that is, the threshold voltage is increased. The difference ΔF2 of Sample C is smaller than that of the reference sample. The smaller difference ΔF2 means that the frequency in Sample C is increased, that is, the threshold voltage is decreased.

In other words, by comparing the difference (difference ΔF2) between the average frequencies of the inspection circuit 112a in which the element circuit 112A is a NOT circuit and the inspection circuit 112c in which the element circuit 112C is a NOR circuit, a variation of the ion concentration of the p-channel can be estimated.

### (Comparison Between NAND Circuit and NOR Circuit)

The difference (difference ΔF3) between the average frequencies of the inspection circuit 112b in which the element circuit 112B is a NAND circuit and the inspection circuit 112c in which the element circuit 112C is a NOR circuit is compared. The difference ΔF3 is substantially equal between the reference sample and Sample A. On the other hand, the difference ΔF3 of Sample B is smaller than that of the reference sample. The difference ΔF3 of Sample C is larger than that of the reference sample. Therefore, by comparing the difference (difference ΔF3) in the average frequency between the inspection circuit 112b in which the element circuit 112B is a NAND circuit and the inspection circuit 112c in which the element circuit 112C is a NOR circuit, the variation in the ion concentration of the n-channel and the p-channel can be more emphasized.

In the above example, the inspection system according to the seventh embodiment is described as an example, but the same applies to the inspection system according to the second or third embodiment using two inspection circuits.

### Operation Example 2

Operation Example 2 where the inspection system according to the present embodiment is operated will be described. Specifically, a case where the element circuits 112A, 112B, and 112C include a NOT circuit 112i2, a NOT circuit 112i3, and a NOT circuit 112i, respectively in the seventh embodiment will be described.

FIG. 31 illustrates the results of simulation under five conditions in total, namely, the standard film thickness, the standard film thickness ±5%, and the standard film thickness ±10%, while changing the insulating film thickness. The horizontal axis of FIG. 31 represents the measurement results (frequencies) in the inspection circuit 112c. The vertical axis of FIG. 31 represents the difference frequency between the measurement results (frequencies) of the inspection circuits 112a and 112b. The frequency is expressed in an arbitrary unit.

Line Lp10 represents the result of the standard film thickness +10%, line Lp05 represents the result of the standard film thickness +5%, line Ltyp represents the result of the standard film thickness, line Lm05 represents the result of the standard film thickness −5%, and line Lm10 represents the result of the standard film thickness −10%. From the result of FIG. 31, the inspection system according to the present embodiment can detect the variation in the thickness of the insulating film.

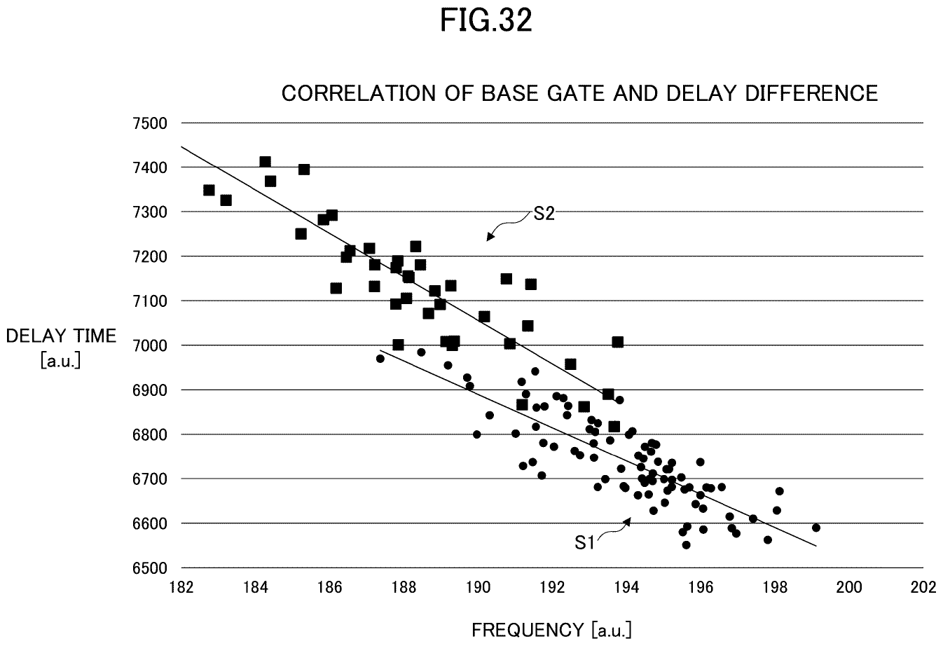

The results of measurement on an actual substrate will be described. FIG. 32 illustrates the measurement results for the case where the insulating film thickness is 0.757 nanometers and the case where the insulating film thickness is 0.620 nanometers. The horizontal axis of FIG. 31 represents the measurement results (frequencies) in the inspection circuit 112c. The vertical axis of FIG. 31 represents the delay time in the inspection circuits 112a and 112b. The frequency and the time are expressed in an arbitrary unit.

The dots S1 indicate the results of the case where the insulating film thickness is 0.620 nanometers, and the dots S2 indicate the results of the case where the insulating film thickness is 0.757 nanometers. From the result of FIG. 32, it can be understood that the inspection system according to the present embodiment can detect the variation in the thickness of the insulating film.

### Operation Example 3

Operation Example 3 where the inspection system according to the present embodiment is operated will be described. Specifically, a case where the element circuits 112A, 112B, and 112C include a NOT circuit 112m1, a NOT circuit 112m2, and a NOT circuit 112m3, respectively in the seventh embodiment will be described. More specifically, the element circuit 112A is a NOT circuit 112m1 in which the gate width of the NMOS transistor 112n1 is equal to the gate width of the PMOS transistor 112p1. The element circuit 112B is a NOT circuit 112m2 in which the gate width of the NMOS transistor 112n1 is shorter than the gate width of the PMOS transistor 112p1. Furthermore, the element circuit 112C is a NOT circuit 112m3 in which the gate width of the PMOS transistor 112p1 is shorter than the gate width of the NMOS transistor 112n1.

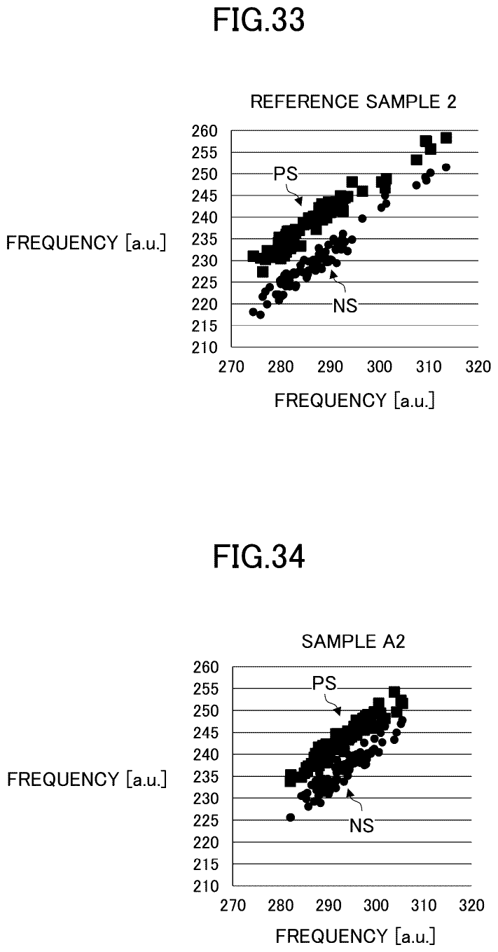

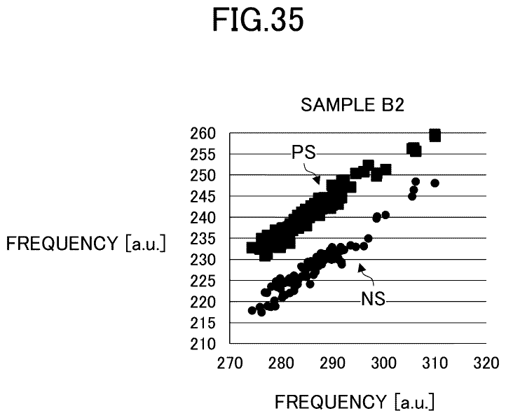

FIGS. 33, 34, and 35 illustrate the results of measuring the frequencies of the outputs of the inspection circuits 112a, 112b, and 112c for the reference sample 2, Sample A2, and Sample B2, respectively. The horizontal axis in each of FIGS. 33, 34, and 35 indicates the measurement results (frequencies) in the inspection circuit 112a as a reference. The vertical axis in each of FIGS. 33, 34, and 35 illustrates the measurement results of the inspection circuits 112b and 112c, respectively. The frequency is expressed in an arbitrary unit. The dots in FIGS. 33, 34, and 35 are the results of measuring the inspection circuits 112a, 112b, and 112c of the plurality of TEGs 312 in one semiconductor substrate 310.

In FIGS. 33, 34, and 35, data PS indicates the measurement result of the inspection circuit 112c. Data NS indicates the measurement result of the inspection circuit 112b.

The reference sample 2 is a semiconductor substrate 310 prepared under normal process conditions. Sample A2 is a semiconductor substrate 310 formed under the condition that the threshold voltage of the NMOS transistor is lowered and the threshold voltage of the PMOS transistor is raised. Sample B2 is a semiconductor substrate 310 formed under the condition that the threshold voltage of the NMOS transistor is raised and the threshold voltage of the PMOS transistor is lowered. In other words, each of Sample A2 and Sample B2 is a sample in which the process conditions are modulated with respect to an ion concentration with respect to the reference sample 2.

Table 2 summarizes the difference between the average frequencies of the inspection circuits 112a and 112b, the difference between the average frequencies of the inspection circuits 112a and 112c, and the difference between the average frequencies of the inspection circuits 112b and 112c. The average frequency is an average of frequencies measured by a plurality of TEGs 312 in one semiconductor substrate 310. In Table 2, the inspection circuits 112a, 112b, and 112c are referred to as “inspection circuit a”, “inspection circuit b”, and “inspection circuit c”, respectively. The difference between the average frequencies of the inspection circuits 112a and 112b is referred to as a “difference ΔF11”, the difference between the average frequencies of the inspection circuits 112a and 112c is referred to as a “difference ΔF12”, and the difference between the average frequencies of the inspection circuits 112b and 112c is referred to as a “difference ΔF13”.

The difference ΔF11 and the difference ΔF12 represent the difference in frequencies from the inspection circuit a (ring oscillator) having the NOT circuit 112m1 as an element circuit, in which the gate width of the PMOS transistor 112p1 and the gate width of the NMOS transistor 112n1 are equal. Since the frequency of the inspection circuit a is higher than the respective frequencies of the inspection circuits b and c, the higher the frequency, the smaller the difference.

TABLE 2

| | Reference | | |
|---|---|---|---|
| | sample 2 | Sample A2 | Sample B2 |
| Difference in average | 47.8 | 49.7 | 45.2 |
| frequency between | | | |
| inspection circuit a and | | | |
| inspection circuit b | | | |
| (Difference ΔF11) | | | |
| Difference in average | 57.4 | 56.8 | 58.4 |
| frequency between | | | |
| inspection circuit a and | | | |
| inspection circuit c | | | |
| (Difference ΔF12) | | | |
| Difference in average | 9.24 | 7.11 | 13.2 |
| frequency between | | | |
| inspection circuit b and | | | |
| inspection circuit c | | | |
| (Difference ΔF13) | | | |

From FIGS. 33, 34, and 35 and Table 2, the difference (difference ΔF11) between the average frequencies of the inspection circuits a and b mainly indicates the threshold characteristic of the p-channel in the PMOS transistor. The difference (difference ΔF12) between the average frequencies of the inspection circuits a and c mainly indicates the threshold characteristic of the n-channel in the NMOS transistor. The difference (difference ΔF13) between the average frequencies of the inspection circuits b and c indicates the p-channel threshold characteristic of the PMOS transistor and the n-channel threshold characteristic of the NMOS transistor.

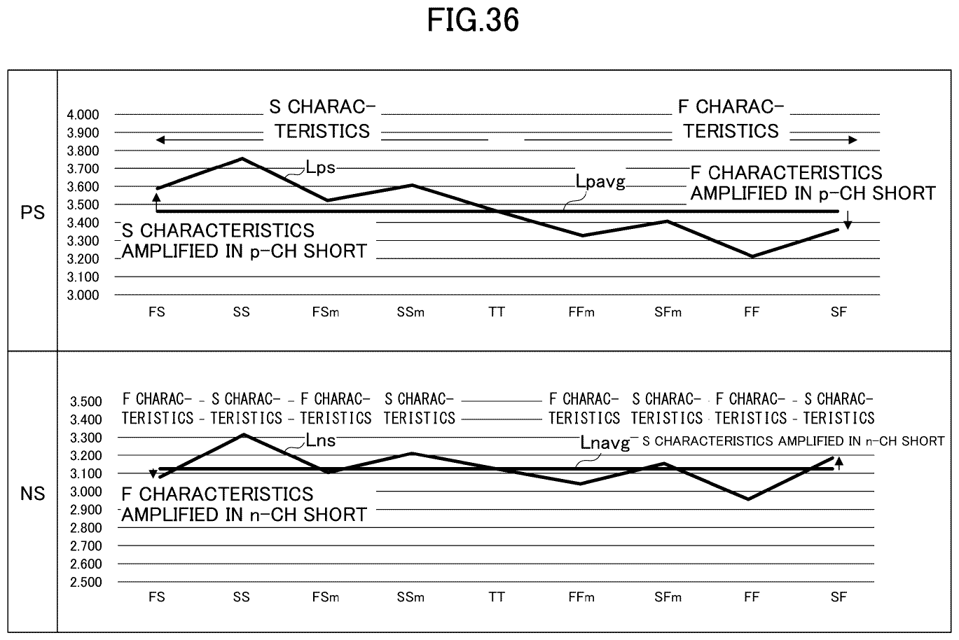

FIG. 36 illustrates the results of simulations in which the manufacturing conditions are changed in the case where the manufacturing conditions are standard and in the case where the threshold values are changed between the n-channel and the p-channel (total of eight conditions).

The horizontal axis in FIG. 36 indicates the manufacturing conditions. “F” represents a manufacturing condition for changing the threshold value so as to operate at a high speed, and “S” represents a manufacturing condition for changing the threshold value so as to operate at a low speed. “F” or “S” on the left side indicates the manufacturing condition for an n-channel, and “F” or “S” on the right side indicates the manufacturing condition for a p-channel. The appended symbol “m” indicates that the conditions are intermediate between the standard conditions for “F” and “S”.

The vertical axis of FIG. 36 indicates the difference between the output of the inspection circuit having the NOT circuit 112m1 as an element circuit and the output of the inspection circuit having the NOT circuit 112m2 or the NOT circuit 112m3 as an element circuit. The frequency is expressed in an arbitrary unit. The upper row (data PS) illustrates the result of the inspection circuit having the NOT circuit 112m3 as an element circuit. The lower row (data NS) illustrates the result of the inspection circuit having the NOT circuit 112m2 as an element circuit.

Line Lps indicates the simulation result under each condition of the result of the inspection circuit having the NOT circuit 112m3 as the element circuit. Line Lpavg represents the mean value of the results of the inspection circuit including the NOT circuit 112m3 as the element circuit under each condition. Line Lns indicates the simulation result under each condition of the result of the inspection circuit having the NOT circuit 112m2 as the element circuit. Line Lnavg represents the mean value of the results of the inspection circuit including the NOT circuit 112m3 as the element circuit under each condition.

According to the results of FIG. 36, for PS, depending on the characteristics of the p-channel, the result is larger than the average in the case of the S-characteristic, and smaller than the average in the case of the F-characteristic. According to the results of FIG. 36, for NS, depending on the characteristics of the n-channel, the result is larger than the average in the case of the S-characteristic, and smaller than the average in the case of the F-characteristic.

As described above, the inspection system according to the present embodiment can detect a variation in an n-channel or a p-channel with emphasis.

### Operation Example 4

Operation Example 4 where the inspection system according to the present embodiment is operated will be described. Specifically, a case where the element circuits 112A and 112B include a NAND circuit 112nd and a NOR circuit 112nr, respectively in the third embodiment will be described.

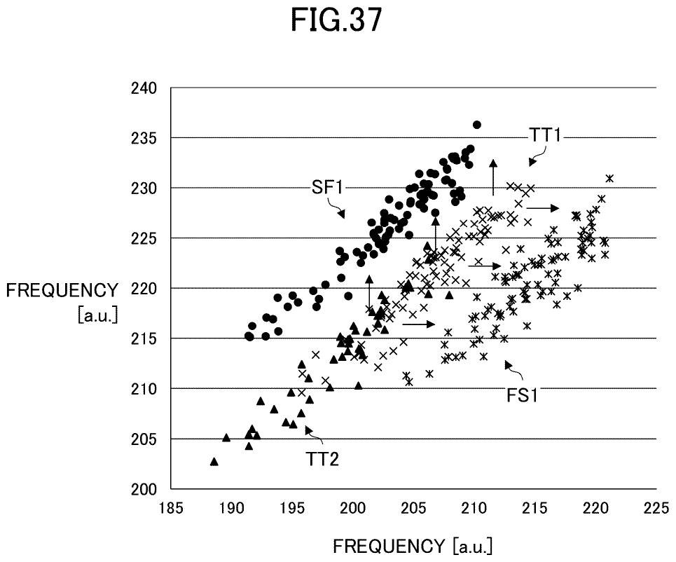

FIG. 37 illustrates the results of measurement under different manufacturing conditions in the case where a NAND circuit and a NOR circuit are used as the element circuits.

The horizontal axis of FIG. 37 represents the result of the inspection circuit 112a using the NAND circuit 112nd as the element circuit 112A. The horizontal axis of FIG. 37 represents the result of the inspection circuit 112b using the NOR circuit 112nr as the element circuit 112B.

In FIG. 37, data TT1 and data TT2 represent data of samples manufactured under standard manufacturing conditions. Data FS1 in FIG. 37 illustrates data of a sample manufactured under manufacturing conditions that provide a threshold value at which the n-channel operates fast and the p-channel operates slow. Data SF1 in FIG. 37 illustrates data of a sample manufactured under manufacturing conditions that provide a threshold value at which the n-channel operates slow and the p-channel operates fast.

As illustrated in FIG. 37, in the case of manufacturing conditions in which the n-channel is fast and the p-channel is slow, the speed of the inspection circuit 112a including the NAND circuit 112nd as an element circuit is faster. In the case of manufacturing conditions in which the n-channel is slow and the p-channel is fast, the speed of the inspection circuit 112b including the NOR circuit 112nr as an element circuit is faster.

As described above, by combining the NAND circuit and the NOR circuit as the element circuits, the state of the process can be estimated from the frequency characteristics.

### Modified Example 1

Modified Example 1 of the NAND circuit and the NOR circuit constituting the element circuit will be described. Although the NAND circuit and the NOR circuit have been described in the third embodiment, the NAND circuit and the NOR circuit are not limited to the examples described in the third embodiment. In Modified Example 1, an example in which the internal connections of the NAND circuit and the NOR circuit are different from each other will be described.

### Modified Example of NAND Circuit

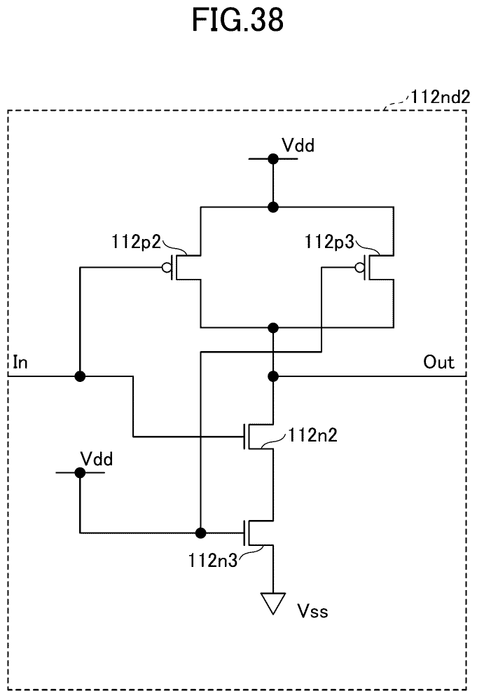

FIG. 38 is a circuit diagram for explaining a modified example of a NAND circuit 112nd as an example of the element circuit included in the inspection circuit of the inspection system according to the present embodiment. Specifically, FIG. 38 is a diagram for explaining a NAND circuit 112nd2 which is a modified example of the NAND circuit 112nd.

In the NAND circuit 112nd in FIG. 8, the NMOS transistor 112n3 is connected to the input In, but in the NAND circuit 112nd2, the NMOS transistor 112n2 is connected to the input In.

The NAND circuit 112nd2 is a NAND circuit. The NAND circuit 112nd2 includes a PMOS transistor 112p2 and a PMOS transistor 112p3, and an NMOS transistor 112n2 and an NMOS transistor 112n3.

Either one of the source or the drain of each of the PMOS transistor 112p2 and the PMOS transistor 112p3 is connected to the power supply potential Vdd. The other of the source or the drain of the PMOS transistor 112p2 and the PMOS transistor 112p3 is connected to either the source or the drain of the NMOS transistor 112n2 and to the output Out of the NAND circuit 112nd2.

The other of the source or the drain of the NMOS transistor 112n2 is connected to either the source or the drain of the NMOS transistor 112n3.

The other of the source or the drain of the NMOS transistor 112n3 is connected to a common potential Vss. The gate of the PMOS transistor 112p2 and the gate of the NMOS transistor 112n2 are connected to the input In of the NAND circuit 112nd2. The gate of the PMOS transistor 112p3 is connected to the gate of the NMOS transistor 112n3 and is connected to a power supply potential Vdd.

The NAND circuit 112nd2 includes an NMOS transistor 112n2 and an NMOS transistor 112n3 connected in series between the power supply potential Vdd and the common potential Vss. Therefore, the NAND circuit 112nd2 is strongly influenced by the n-channels of the NMOS transistor 112n2 and the NMOS transistor 112n3. Since the NAND circuit 112nd2 is strongly influenced by an n-channel, the NAND circuit 112nd2 is strongly influenced by an n-channel when the ion concentration of an n-channel varies. Therefore, by employing the NAND circuit 112nd2 as an element circuit in either the inspection circuit 112a, the inspection circuit 112b, or the inspection circuit 112c, it is possible to detect a variation in the ion concentration of an n-channel as process variation.

Since the gate of the NMOS transistor 112n3 of the NAND circuit 112nd2 is connected to the power supply potential Vdd, the potential of the NAND circuit 112nd2 is fixed. Therefore, the NMOS transistor 112n3 can be regarded as a resistance component that does not fluctuate. Therefore, the NAND circuit 112nd2 differs from the NAND circuit 112nd in the effect of the variation due to the ion concentration of the n-channel, as compared with the NAND circuit 112nd. Therefore, the NAND circuit 112nd2 has characteristics different from those of the NAND circuit 112nd, and can investigate the influence of the variation due to the ion concentration of the n-channel.

### Modified Example of NOR Circuit

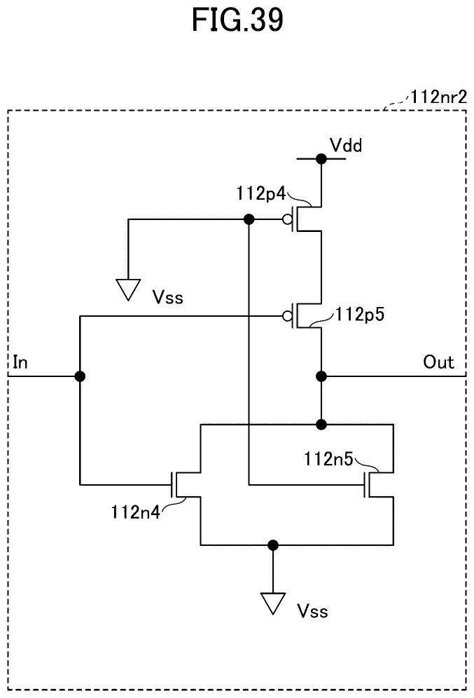

FIG. 39 is a circuit diagram for explaining a modified example of a NOR circuit 112nr as an example of the element circuit included in the inspection circuit of the inspection system according to the present embodiment. Specifically, FIG. 39 is a diagram for explaining a NOR circuit 112nr2 which is a modified example of the NOR circuit 112nr.

In the NOR circuit 112nr in FIG. 9, the PMOS transistor 112p4 is connected to the input In, but in the NOR circuit 112nr2, the PMOS transistor 112p5 is connected to the input In.

The NOR circuit 112nr2 is a NOR circuit. The NOR circuit 112nr2 includes a PMOS transistor 112p4 and a PMOS transistor 112p5, and an NMOS transistor 112n4 and an NMOS transistor 112n5.

Either one of the source or the drain of the PMOS transistor 112p4 is connected to a power supply potential Vdd. The other of the source or the drain of the PMOS transistor 112p4 is connected to either the source or the drain of the PMOS transistor 112p5. The other of the source or the drain of the PMOS transistor 112p5 is connected to either the source or the drain of each of the NMOS transistor 112n4 and the NMOS transistor 112n5 and to the output Out of the NOR circuit 112nr2.

The other of the source or the drain of each of the NMOS transistor 112n4 and the NMOS transistor 112n5 is connected to a common potential Vss. The gate of the PMOS transistor 112p5 and the gate of the NMOS transistor 112n4 are connected to the input In of the NOR circuit 112nr2. The gate of the PMOS transistor 112p4 is connected to the gate of the NMOS transistor 112n5 and is connected to the common potential Vss.

The NOR circuit 112nr2 includes a PMOS transistor 112p4 and a PMOS transistor 112p5 connected in series between the power supply potential Vdd and the common potential Vss. Therefore, the NOR circuit 112nr2 is strongly influenced by the p-channels of the PMOS transistor 112p4 and the PMOS transistor 112p5. Since the NOR circuit 112nr2 is strongly influenced by a p-channel, the NOR circuit 112nr2 is strongly influenced by a p-channel when the ion concentration of a p-channel varies. Therefore, by employing the NOR circuit 112nr2 as an element circuit in either the inspection circuit 112a, the inspection circuit 112b, or the inspection circuit 112c, it is possible to detect a variation in the ion concentration of a p-channel as process variation.

Since the gate of the PMOS transistor 112p4 of the NOR circuit 112nr2 is connected to the common potential Vss, the potential of the NOR circuit 112nr2 is fixed. Therefore, the PMOS transistor 112p4 can be regarded as a resistance component that does not fluctuate. Therefore, the NOR circuit 112nr2 differs from the NOR circuit 112nr in the effect of the variation due to the ion concentration of the p-channel, as compared with the NOR circuit 112nr. Therefore, the NOR circuit 112nr2 has characteristics different from those of the NOR circuit 112nr, and can investigate the influence of the variation due to the ion concentration of the p-channel.

### Modified Example 2

Modified Example 2 of the NAND circuit and the NOR circuit constituting the element circuit will be described. Although the NAND circuit and the NOR circuit have been described in the third embodiment, the NAND circuit and the NOR circuit are not limited to the examples described in the third embodiment. In Modified Example 2, an example in which the number of inputs is different for each of the NAND circuit and the NOR circuit will be described.

### Modified Example of NAND Circuit

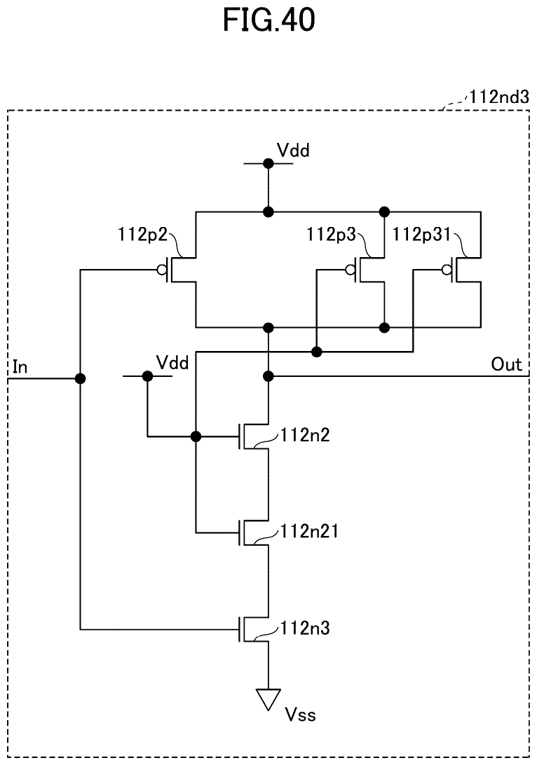

FIG. 40 is a circuit diagram for explaining a modified example of a NAND circuit 112nd as an example of the element circuit included in the inspection circuit of the inspection system according to the present embodiment. Specifically, FIG. 40 is a diagram for explaining a NAND circuit 112nd3 which is a modified example of the NAND circuit 112nd.

The NAND circuit 112nd in FIG. 8 is a two-input NAND circuit, but the NAND circuit 112nd3 is a three-input NAND circuit.

The NAND circuit 112nd3 is a NAND circuit having three inputs. The NAND circuit 112nd3 has a PMOS transistor 112p31 and an NMOS transistor 112n21 in addition to the configuration of the NAND circuit 112nd.

The PMOS transistor 112p31 is provided in parallel with the PMOS transistor 112p3. The NMOS transistor 112n21 is provided in series between the NMOS transistor 112n2 and the NMOS transistor 112n3.

In the NAND circuit 112nd, two n-channel transistors are connected in series between the power supply potential Vdd and the common potential Vss. The load seen from the n-channel transistor to be turned on and off includes a resistive load (n-channel transistor) and a capacitive load (p-channel and n-channel transistors in the next stage). The load seen from the p-channel transistor to be turned on and off is only a capacitive load (p-channel and n-channel transistors in the next stage). Therefore, the NAND circuit 112nd is sensitive to a variation in the n-channel.

In the NAND circuit 112nd3, which is a three-input NAND circuit, two n-channel transistors are seen as serially resistive loads as viewed from the n-channel transistor to be turned on and off. The load seen from the p-channel transistor to be turned on and off has no series resistive load, as in the NAND circuit 112nd, which is a two-input NAND circuit. Therefore, by using the three-input NAND circuit, the sensitivity to a variation in the n-channel is further increased.

### Modified Example of NOR Circuit

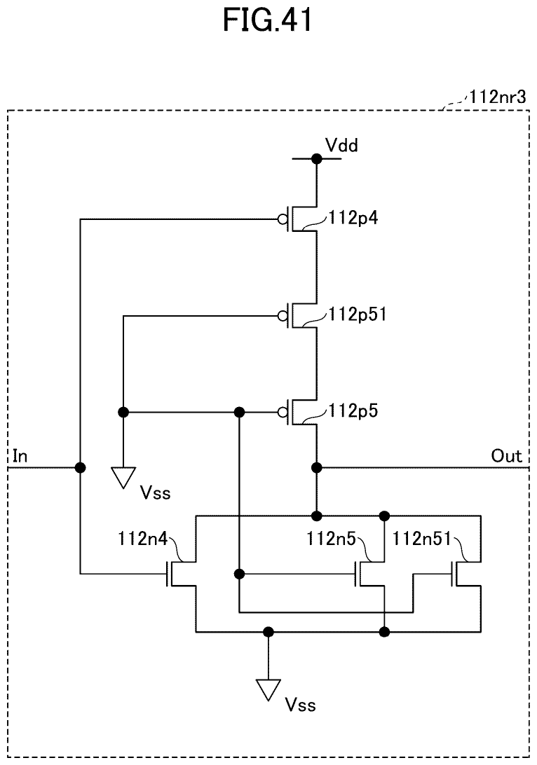

FIG. 41 is a circuit diagram for explaining a modified example of a NOR circuit 112nr as an example of the element circuit included in the inspection circuit of the inspection system according to the present embodiment. Specifically, FIG. 41 is a diagram for explaining a NOR circuit 112nr3 which is a modified example of the NOR circuit 112nr.

The NOR circuit 112nr in FIG. 9 is a two-input NOR circuit, but the NOR circuit 112nr3 is a three-input NOR circuit.

The NOR circuit 112nr3 is a NOR circuit having three inputs. The NOR circuit 112nr3 has a PMOS transistor 112p51 and an NMOS transistor 112n51 in addition to the configuration of the NOR circuit 112nr.

The PMOS transistor 112p51 is provided in series between the PMOS transistor 112p4 and the PMOS transistor 112p5. The NMOS transistor 112n51 is provided in parallel with the NMOS transistor 112n5.

In the NOR circuit 112nr, two p-channel transistors are connected in series between the power supply potential Vdd and the common potential Vss. The load seen from the p-channel transistor to be turned on and off includes a resistive load (p-channel transistor) and a capacitive load (p-channel and n-channel transistors in the next stage). The load seen from the n-channel transistor to be turned on and off is only a capacitive load (p-channel and n-channel transistors in the next stage). Therefore, the NOR circuit 112nr is sensitive to a variation in the p-channel.

In the NOR circuit 112nr3, which is a three-input NOR circuit, two p-channel transistors are seen as serially resistive loads as viewed from the p-channel transistor to be turned on and off. The load seen from the n-channel transistor to be turned on and off has no series resistive load, as in the NOR circuit 112nr, which is a two-input NOR circuit. Therefore, by using the three-input NOR circuit, the sensitivity to a variation in the p-channel is further increased.

In the above description, the NAND circuit or the NOR circuit having three inputs is described, but the inputs may be four or more inputs. Further, as in Modified Example 1, the transistors connected to the inputs of the respective circuits may be changed, and the number of transistors for fixing the gate potential may also be changed.

The inspection system and inspection method according to the embodiment disclosed herein is merely an example in all respects and should not be construed as being limited thereto. The above-described embodiments may be modified and improved in various forms without departing from the scope and spirit of the appended claims. The matters described in the plurality of embodiments can be combined with each other within a range not inconsistent with each other.

What is claimed is:

1. An inspection system, comprising:
a semiconductor substrate on which a first inspection circuit and a second inspection circuit are formed;
a measurer configured to measure a predetermined characteristic in each of the first inspection circuit and the second inspection circuit; and
an estimator configured to estimate process variation when the first inspection circuit and the second inspection circuit are formed on the semiconductor substrate, based on a first measurement result obtained by the measurer measuring the first inspection circuit and a second measurement result obtained by the measurer measuring the second inspection circuit, wherein
a magnitude of a variation of the characteristic with respect to the process variation in the second inspection circuit differs from a magnitude of a variation of the characteristic with respect to the process variation in the first inspection circuit.

2. The inspection system according to claim 1, wherein
the first inspection circuit is a ring oscillation circuit in which a plurality of first element circuits are connected in series and an output of a final stage is input to a foremost stage,
the second inspection circuit is a ring oscillation circuit in which a plurality of second element circuits are connected in series and an output of a final stage is input to a foremost stage, and
the characteristic is a frequency.

3. The inspection system according to claim 2, wherein
the first element circuit is a NOT circuit, and
the second element circuit is a NAND circuit.

4. The inspection system according to claim 3, wherein
the first element circuit includes a first PMOS transistor having a p-channel and a first NMOS transistor having an n-channel,
either one of a source or a drain of the first PMOS transistor is connected to a power supply potential,
the other of the source or the drain of the first PMOS transistor is connected to either one of a source or a drain of the first NMOS transistor and is connected to an output of the first element circuit,
the other of the source or the drain of the first NMOS transistor is connected to a common potential,
a gate of the first PMOS transistor and a gate of the first NMOS transistor are connected to an input of the first element circuit,
the second element circuit includes a second PMOS transistor and a third PMOS transistor each having a p-channel, and a second NMOS transistor and a third NMOS transistor each having an n-channel,
either one of a source or a drain of each of the second PMOS transistor and the third PMOS transistor is connected to the power supply potential,
the other of the source or the drain of each of the second PMOS transistor and the third PMOS transistor is connected to either one of a source or a drain of the second NMOS transistor and is connected to an output of the second element circuit,
the other of the source or the drain of the second NMOS transistor is connected to either one of a source or a drain of the third NMOS transistor,
the other of the source or the drain of the third NMOS transistor is connected to a common potential,
a gate of the second PMOS transistor and a gate of the third NMOS transistor are connected to an input of the second element circuit, and
a gate of the third PMOS transistor is connected to a gate of the second NMOS transistor and is connected to the power supply potential.

5. The inspection system according to claim 2, wherein
the first element circuit is a NOT circuit, and
the second element circuit is a NOR circuit.

6. The inspection system according to claim 5, wherein
the first element circuit includes a first PMOS transistor having a p-channel and a first NMOS transistor having an n-channel,
either one of a source or a drain of the first PMOS transistor is connected to a power supply potential,
the other of the source or the drain of the first PMOS transistor is connected to either one of a source or a drain of the first NMOS transistor and is connected to an output of the first element circuit,
the other of the source or the drain of the first NMOS transistor is connected to a common potential,
a gate of the first PMOS transistor and a gate of the first NMOS transistor are connected to an input of the first element circuit,
the second element circuit includes a fourth PMOS transistor and a fifth PMOS transistor each having a p-channel, and a fourth NMOS transistor and a fifth NMOS transistor each having an n-channel,
either one of a source or a drain of the fourth PMOS transistor is connected to the power supply potential,
the other of the source or the drain of the fourth PMOS transistor is connected to either one of a source or a drain of the fifth PMOS transistor,
the other of the source or the drain of the fifth PMOS transistor is connected to either one of a source or a drain of each of the fourth NMOS transistor and the fifth NMOS transistor and is connected to an output of the second element circuit,
either one of a source or a drain of each of the fourth NMOS transistor and the fifth NMOS transistor is connected to the common potential,
a gate of the fourth PMOS transistor and a gate of the fourth NMOS transistor are connected to an input of the second element circuit, and
a gate of the fifth PMOS transistor is connected to a gate of the fifth NMOS transistor and is connected to the common potential.

7. The inspection system according to claim 2, wherein
the first element circuit is a NAND circuit, and
the second element circuit is a NOR circuit.

8. The inspection system according to claim 7, wherein
the first element circuit includes a second PMOS transistor and a third PMOS transistor each having a p-channel, and a second NMOS transistor and a third NMOS transistor each having an n-channel,
either one of a source or a drain of each of the second PMOS transistor and the third PMOS transistor is connected to a power supply potential,
the other of the source or the drain of each of the second PMOS transistor and the third PMOS transistor is connected to either one of a source or a drain of the second NMOS transistor and is connected to an output of the second element circuit,
the other of the source or the drain of the second NMOS transistor is connected to either one of a source or a drain of the third NMOS transistor,
the other of the source or the drain of the third NMOS transistor is connected to a common potential,
a gate of the second PMOS transistor and a gate of the third NMOS transistor are connected to an input of the second element circuit,
a gate of the third PMOS transistor is connected to a gate of the second NMOS transistor and is connected to the power supply potential,
the second element circuit includes a fourth PMOS transistor and a fifth PMOS transistor each having a p-channel, and a fourth NMOS transistor and a fifth NMOS transistor each having an n-channel,
either one of a source or a drain of the fourth PMOS transistor is connected to the power supply potential,
the other of the source or the drain of the fourth PMOS transistor is connected to either one of a source or a drain of the fifth PMOS transistor,
the other of the source or the drain of the fifth PMOS transistor is connected to either one of a source or a drain of each of the fourth NMOS transistor and the fifth NMOS transistor and is connected to the output of the second element circuit,
either one of a source or a drain of each of the fourth NMOS transistor and the fifth NMOS transistor is connected to the power supply potential,
a gate of the fourth PMOS transistor and a gate of the fourth NMOS transistor are connected to the input of the second element circuit, and
a gate of the fifth PMOS transistor is connected to a gate of the fifth NMOS transistor and is connected to the common potential.

9. The inspection system according to claim 2, wherein
the first element circuit includes a plurality of NOT circuits, and respective inputs of the plurality of NOT circuits are connected to an input of the first element circuit, and
the second element circuit is a NOT circuit.

10. The inspection system according to claim 9, wherein
the first element circuit includes
a NOT circuit having a sixth PMOS transistor having a p-channel and a sixth NMOS transistor having an n-channel;
a first dummy NOT circuit having a seventh PMOS transistor having a p-channel and a seventh NMOS transistor having an n-channel; and
a second dummy NOT circuit having an eighth PMOS transistor having a p-channel and an eighth NMOS transistor having an n-channel,
either one of a source or a drain of the sixth PMOS transistor is connected to a power supply potential,
the other of the source or the drain of the sixth PMOS transistor is connected to either one of a source or a drain of the sixth NMOS transistor and is connected to an output of the first element circuit,
the other of the source or the drain of the sixth NMOS transistor is connected to a common potential,
a gate of the sixth PMOS transistor and a gate of the sixth NMOS transistor are connected to an input of the first element circuit,
either one of a source or a drain of the seventh PMOS transistor is connected to the power supply potential,
the other of the source or the drain of the seventh PMOS transistor is connected to either one of a source or a drain of the seventh NMOS transistor,
the other of the source or the drain of the seventh NMOS transistor is connected to the common potential,
a gate of the seventh PMOS transistor and a gate of the seventh NMOS transistor are connected to the input of the first element circuit,
either one of a source or a drain of the eighth PMOS transistor is connected to the power supply potential,
the other of the source or the drain of the eighth PMOS transistor is connected to either one of a source or a drain of the eighth NMOS transistor,
the other of the source or the drain of the eighth NMOS transistor is connected to the common potential,
a gate of the eighth PMOS transistor and a gate of the eighth NMOS transistor are connected to the input of the first element circuit,
the second element circuit includes
a ninth PMOS transistor having a p-channel;
a ninth NMOS transistor having an n-channel;
a first dummy interconnect; and
a second dummy interconnect,
either one of a source or a drain of the ninth PMOS transistor is connected to the power supply potential,
the other of the source or the drain of the ninth transistor is connected to either one of a source or a drain of the ninth NMOS transistor and is connected to an output of the second element circuit,
the other of the source or the drain of the ninth NMOS transistor is connected to the common potential,
a gate of the ninth PMOS transistor and a gate of the ninth NMOS transistor are connected to an input of the second element circuit,
the first dummy interconnect is an interconnect having a same configuration as an interconnect from the input to the first dummy NOT circuit in the first element circuit, and
the second dummy interconnect is a interconnect having a same configuration as an interconnect from the input to the second dummy NOT circuit in the first element circuit.

11. The inspection system according to claim 2, wherein
the second element circuit has a same circuit configuration as the first element circuit, and
a gate width of a transistor constituting the second element circuit differs from a gate width of a transistor constituting the first element circuit corresponding to the transistor.

12. The inspection system according to claim 11, wherein
the first element circuit and the second element circuit are any one of a NOT circuit, a NAND circuit, or a NOR circuit.

13. The inspection system according to claim 11, wherein
the first element circuit is a NOT circuit having a tenth PMOS transistor having a p-channel and a tenth NMOS transistor having an n-channel,
either one of a source or a drain of the tenth PMOS transistor is connected to a power supply potential,
the other of the source or the drain of the tenth PMOS transistor is connected to either one of a source or a drain of the tenth NMOS transistor and is connected to an output of the first element circuit,
the other of the source or the drain of the tenth NMOS transistor is connected to a common potential,
a gate of the tenth PMOS transistor and a gate of the tenth NMOS transistor are connected to an input of the first element circuit,
the second element circuit is a NOT circuit having an eleventh PMOS transistor having a p-channel and an eleventh NMOS transistor having an n-channel,
either one of a source or a drain of the eleventh PMOS transistor is connected to the power supply potential,
the other of the source or the drain of the eleventh PMOS transistor is connected to either one of a source or a drain of the eleventh NMOS transistor and is connected to an output of the second element circuit,
the other of the source or the drain of the eleventh NMOS transistor is connected to the common potential,
a gate of the eleventh PMOS transistor and a gate of the eleventh NMOS transistor are connected to an input of the second element circuit, and
a gate width of the eleventh PMOS transistor differs from a gate width of the tenth PMOS transistor, or a gate width of the eleventh NMOS transistor differs from a gate width of the tenth NMOS transistor.

14. The inspection system according to claim 1, wherein
the semiconductor substrate further includes a third inspection circuit,
the measurer measures the characteristic in the third inspection circuit,
the estimator estimates the process variation when the first inspection circuit, the second inspection circuit, and the third inspection circuit are formed on the semiconductor substrate, based on the first measurement result, the second measurement result, and a third measurement result obtained by the measurer measuring the third inspection circuit, and
a magnitude of a variation of the characteristic with respect to the process variation in the third inspection circuit differs from a magnitude of a variation of the characteristic with respect to the process variation in each of the first inspection circuit and the second inspection circuit.

15. The inspection system according to claim 14, wherein
the first inspection circuit is a ring oscillation circuit in which a plurality of first element circuits are connected in series and an output of a final stage is input to a foremost stage,
the second inspection circuit is a ring oscillation circuit in which a plurality of second element circuits are connected in series and an output of a final stage is input to a foremost stage,
the third inspection circuit is a ring oscillation circuit in which a plurality of third element circuits are connected in series and an output of a final stage is input to a foremost stage, and
the characteristic is a frequency.

16. The inspection system according to claim 15, wherein
the first element circuit is a NOT circuit,
the second element circuit is a NAND circuit, and
the third element circuit is a NOR circuit.

17. The inspection system according to claim 16, wherein
the first element circuit includes
a first PMOS transistor having a p-channel; and
a first NMOS transistor having an n-channel,
either one of a source or a drain of the first PMOS transistor is connected to a power supply potential,
the other of the source or the drain of the first PMOS transistor is connected to either one of a source or a drain of the first NMOS transistor and is connected to an output of the first element circuit,
the other of the source or the drain of the first NMOS transistor is connected to a common potential,
a gate of the first PMOS transistor and a gate of the first NMOS transistor are connected to an input of the first element circuit,
the second element circuit includes
a second PMOS transistor and a third PMOS transistor each having a p-channel; and
a second NMOS transistor and a third NMOS transistor each having an n-channel,
either one of a source or a drain of each of the second PMOS transistor and the third PMOS transistor is connected to the power supply potential,
the other of the source or the drain of each of the second PMOS transistor and the third PMOS transistor is connected to either one of a source or a drain of the second NMOS transistor and is connected to an output of the second element circuit,
the other of the source or the drain of the second NMOS transistor is connected to either one of a source or a drain of the third NMOS transistor,
the other of the source or the drain of the third NMOS transistor is connected to the common potential,
a gate of the second PMOS transistor and a gate of the third NMOS transistor are connected to an input of the second element circuit,
a gate of the third PMOS transistor is connected to a gate of the second NMOS transistor and is connected to the power supply potential,
the third element circuit includes
a fourth PMOS transistor and a fifth PMOS transistor each having a p-channel; and
a fourth NMOS transistor and a fifth NMOS transistor each having an n-channel,
either one of a source or a drain of the fourth PMOS transistor is connected to the power supply potential,
the other of the source or the drain of the fourth NMOS transistor is connected to either one of a source or a drain of the fifth NMOS transistor,
the other of the source or the drain of the fifth PMOS transistor is connected to either one of the source or the drain of each of the fourth NMOS transistor and the fifth NMOS transistor and is connected to an output of the third element circuit,
the other of the source or the drain of each of the fourth NMOS transistor and the fifth NMOS transistor is connected to the common potential,
a gate of the fourth PMOS transistor and a gate of the fourth NMOS transistor are connected to an input of the third element circuit, and
a gate of the fifth PMOS transistor is connected to a gate of the fifth NMOS transistor and is connected to the common potential.

18. The inspection system according to claim 15, wherein
the first element circuit is a NOT circuit,
the second element circuit includes a plurality of NOT circuits, and respective inputs of the plurality of NOT circuits are connected to an input of the second element circuit, and
the third element circuit is a NOT circuit including a dummy interconnect.

19. The inspection system according to claim 18, wherein
the first element circuit includes
a first PMOS transistor having a p-channel; and
a first NMOS transistor having an n-channel,
either one of a source or a drain of the first PMOS transistor is connected to a power supply potential,
the other of the source or the drain of the first PMOS transistor is connected to either one of a source or a drain of the first NMOS transistor and is connected to an output of the first element circuit,
the other of the source or the drain of the first NMOS transistor is connected to a common potential,
a gate of the first PMOS transistor and a gate of the first NMOS transistor are connected to an input of the first element circuit,
the second element circuit includes
a NOT circuit having a sixth PMOS transistor having a p-channel and a sixth NMOS transistor having an n-channel;
a first dummy NOT circuit having a seventh PMOS transistor having a p-channel and a seventh NMOS transistor having an n-channel; and
a second dummy NOT circuit having an eighth PMOS transistor having a p-channel and an eighth NMOS transistor having an n-channel,
either one of a source or a drain of the sixth PMOS transistor is connected to the power supply potential,
the other of the source or the drain of the sixth PMOS transistor is connected to either one of a source or a drain of the sixth NMOS transistor and is connected to an output of the second element circuit,
the other of the source or the drain of the sixth NMOS transistor is connected to the common potential,
a gate of the sixth PMOS transistor and a gate of the sixth NMOS transistor are connected to an input of the second element circuit,
either one of a source or a drain of the seventh PMOS transistor is connected to the power supply potential,
the other of the source or the drain of the seventh PMOS transistor is connected to either one of a source or a drain of the seventh NMOS transistor,
the other of the source or the drain of the seventh NMOS transistor is connected to the common potential,
a gate of the seventh PMOS transistor and a gate of the seventh NMOS transistor are connected to an input of the second element circuit,
either one of a source or a drain of the eighth PMOS transistor is connected to the power supply potential,
the other of the source or the drain of the eighth PMOS transistor is connected to either one of a source or a drain of the eighth NMOS transistor,
the other of the source or the drain of the eighth NMOS transistor is connected to the common potential,
a gate of the eighth PMOS transistor and a gate of the eighth NMOS transistor are connected to an input of the second element circuit,
the third element circuit includes
a ninth PMOS transistor having a p-channel;
a ninth NMOS transistor having an n-channel;
a first dummy interconnect; and
a second dummy interconnect,
either one of a source or a drain of the ninth PMOS transistor is connected to the power supply potential,
the other of the source or the drain of the ninth PMOS transistor is connected to either one of a source or a drain of the ninth NMOS transistor and is connected to an output of the third element circuit,
the other of the source or the drain of the ninth NMOS transistor is connected to the common potential,
a gate of the ninth PMOS transistor and a gate of the ninth NMOS transistor are connected to an input of the third element circuit,
the first dummy interconnect is a interconnect having a same configuration as an interconnect from the input to the first dummy NOT circuit in the second element circuit, and
the second dummy interconnect is a interconnect having a same configuration as an interconnect from the input to the second dummy NOT circuit in the second element circuit.

20. The inspection system according to claim 14, wherein
the semiconductor substrate has a plurality of chip forming regions and a cutting region for cutting the plurality of chip forming regions into each of the chip forming regions, and
each of the first inspection circuit, the second inspection circuit, and the third inspection circuit is formed in the cutting region.
